(19) United States
(12) Patent Application Publication
(10) Pub. No.: US 2026/0047401 A1
(43) Pub. Date: Feb. 12, 2026

(54) SEMICONDUCTOR PACKAGE AND METHOD OF MANUFACTURING THE SAME

(71) Applicant: Samsung Electronics Co., Ltd., Suwon-si (KR)

(72) Inventor: Seonho Lee, Suwon-si (KR)

(21) Appl. No.: 19/283,431

(22) Filed: Jul. 29, 2025

(30) Foreign Application Priority Data
Aug. 7, 2024 (KR) 10-2024-0105751

(51) Int. Cl. H01L 21/027; H01L 21/48; H01L 21/56; H01L 23/00; H01L 23/498; H01L 25/065; H10B 80/00; H10D 80/30

(52) U.S. Cl. CPC H01L 21/0272; H01L 21/4853; H01L 21/565; H01L 23/49838; H01L 24/11; H01L 24/13; H01L 24/14; H01L 24/16; H01L 25/0657; H01L 24/32; H01L 24/73; H01L 25/0655; H01L 2224/1146; H01L 2224/11474; H01L 2224/13017; H01L 2224/13018; H01L 2224/13552; H01L 2224/13553; H01L 2224/1403; H01L 2224/16227; H01L 2224/16238; H01L 2224/32145; H01L 2224/32225; H01L 2224/73203; H01L 2224/73253; H01L 2225/06517; H01L 2225/06524; H01L 2225/06562; H01L 2924/14361; H10B 80/00; H10D 80/30

(57) ABSTRACT

Semiconductor packages, and methods for manufacturing semiconductor packages are provided. In one aspect, a method of manufacturing a semiconductor package includes stacking a plurality of semiconductor chips including a first semiconductor chip and a second semiconductor chip, the first semiconductor ship being offset from the second semiconductor ship to expose upper connection pads; forming a multilayered photoresist film to cover the plurality of semiconductor chips; forming a plurality of openings by exposing and developing the multilayered photoresist film; forming a plurality of conductive posts by filling the plurality of openings with a conductive material; removing the multilayered photoresist film; forming a molding encapsulant to surround the plurality of semiconductor chips and the plurality of conductive posts; and forming a wiring structure electrically connected to the plurality of conductive posts. The multilayered photoresist film comprises at least two layers having different chemical resistances and resolutions.

### CROSS-REFERENCE TO RELATED APPLICATION

This application is based on and claims priority under 35 U.S.C. § 119 to Korean Patent Application No. 10-2024-0105751, filed on Aug. 7, 2024, in the Korean Intellectual Property Office, the disclosure of which is incorporated by reference herein in its entirety.

### BACKGROUND

With the rapid development of the electronics industry and the demands of users, electronic devices are becoming smaller, more multifunctional, and larger in capacity, and thus, highly integrated semiconductor chips are desired. Accordingly, a semiconductor package including a highly integrated semiconductor chip with an increased number of input/output (I/O) connection terminals while ensuring connection reliability may be designed. For example, to restrict interference between connection patterns, a semiconductor package has been developed to increase a distance between the connection patterns and aspect ratios of the connection patterns.

### SUMMARY

The present disclosure provides a semiconductor package having improved reliability and productivity by accurately forming a conductive post with a high aspect ratio according to design rules using a multilayered photoresist film, and a method of manufacturing the semiconductor package.

The present disclosure also provides a semiconductor package having improved reliability and productivity by accurately forming a bump structure with a high aspect ratio according to design rules using a multilayered photoresist film, and a method of manufacturing the semiconductor package.

The technical objectives of the present disclosure are not limited to the above disclosure; other objectives may become apparent to those of ordinary skill in the art based on the following descriptions.

According to an aspect of the present disclosure, a method of manufacturing a semiconductor package is provided. The method includes sequentially stacking a plurality of semiconductor chips by shifting each of the plurality of semiconductor chips a predetermined distance from an edge of a semiconductor chip located thereunder in a lateral direction to expose a plurality of upper connection pads formed on an outer region of a top surface of the semiconductor chip located thereunder, adhering a multilayered photoresist film to the resultant structure to cover the plurality of semiconductor chips, forming a plurality of openings in an outer region of the top surface of the semiconductor chip by exposing and developing the multilayered photoresist film, forming a plurality of conductive posts by filling the plurality of openings with a conductive material, the plurality of conductive posts being connected to the plurality of upper connection pads on an outer region of the top surface of the semiconductor chip, removing the multilayered photoresist film, forming a molding member to surround the plurality of semiconductor chips and the plurality of conductive posts, and forming a wiring structure on the molding member, the wiring structure being electrically connected to the plurality of conductive posts, wherein the multilayered photoresist film includes at least two layers having different chemical resistances and resolutions.

According to another aspect of the present disclosure, a method of manufacturing a semiconductor package is provided. The method includes providing a semiconductor substrate including a plurality of electrode pads, forming, on the semiconductor substrate, a protective layer exposing the plurality of electrode pads, forming a seed layer to conformally cover the protective layer and the plurality of electrode pads, adhering a multilayered photoresist film to the resultant structure to cover the seed layer, forming a plurality of openings exposing the seed layer on the plurality of electrode pads by exposing and developing the multilayered photoresist film, forming a plurality of bump structures by filling the plurality of openings with a conductive material, the plurality of bump structures being connected to the plurality of electrode pads in the semiconductor substrate, removing the multilayered photoresist film, and removing the seed layer around the plurality of bump structures, wherein the multilayered photoresist film includes at least two layers having different chemical resistances and resolutions.

According to another aspect of the present disclosure, a semiconductor package is provided, which includes a package substrate, a plurality of semiconductor chips sequentially stacked on the package substrate by shifting each of the plurality of semiconductor chips a predetermined distance from an edge of a semiconductor chip located thereunder in a lateral direction to expose a plurality of upper connection pads formed on an outer region of a top surface of the semiconductor chip located thereunder, a plurality of conductive posts respectively connected to the plurality of upper connection pads on an outer region of a top surface of any one of the plurality of semiconductor chips, a molding member surrounding the plurality of semiconductor chips and the plurality of conductive posts, and a wiring structure on the molding member, the wiring structure being electrically connected to the plurality of conductive posts, wherein each of the plurality of conductive posts includes a lower portion and an upper portion on the upper connection pad, and a slope of a sidewall of the conductive post is changed between the lower portion and the upper portion.

### BRIEF DESCRIPTION OF THE DRAWINGS

Implementations will be more clearly understood from the following detailed description taken in conjunction with the accompanying drawings in which:

FIG. 1 is a cross-sectional view of an example semiconductor package;

FIG. 2 is an enlarged cross-sectional view of portion AA of FIG. 1;

FIG. 3 is an enlarged cross-sectional view of portion BB of FIG. 2;

FIG. 4 is a cross-sectional view of another example semiconductor package;

FIG. 5 is an enlarged cross-sectional view of portion CC of FIG. 4;

FIG. 6 is a flowchart of an example method of manufacturing a semiconductor package;

FIGS. 7 to 18 are cross-sectional views of an example process sequence of a method of manufacturing a semiconductor package;

FIG. 19 is a flowchart of an example method of manufacturing a semiconductor package;

FIGS. 20 to 31 are cross-sectional views of an example process sequence of a method of manufacturing a semiconductor package; and

FIG. 32 is a view showing the configuration of an example semiconductor package.

### DETAILED DESCRIPTION

Hereinafter, implementations will be described in detail with reference to the accompanying drawings.

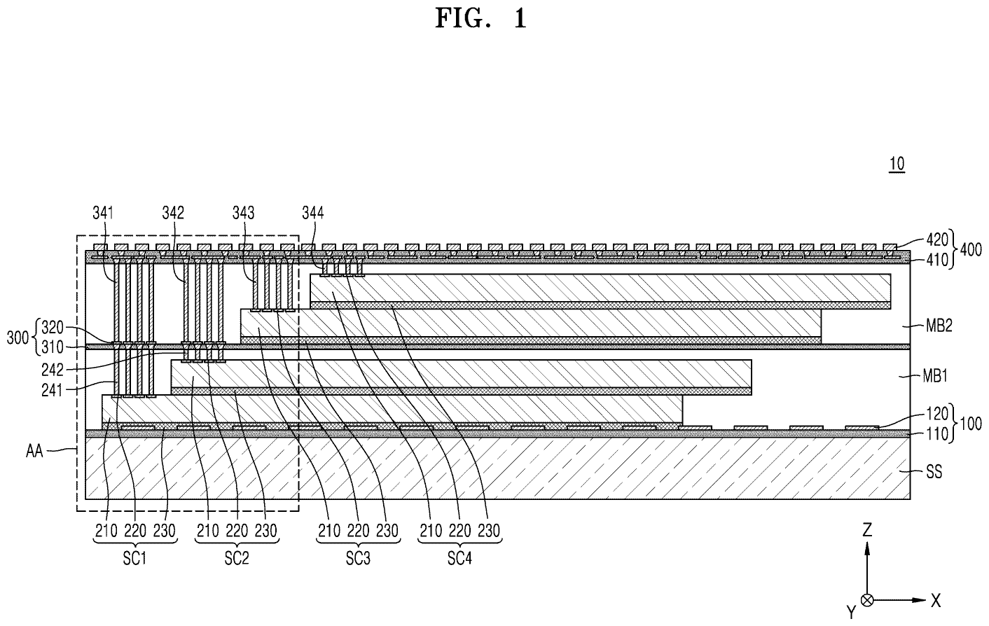

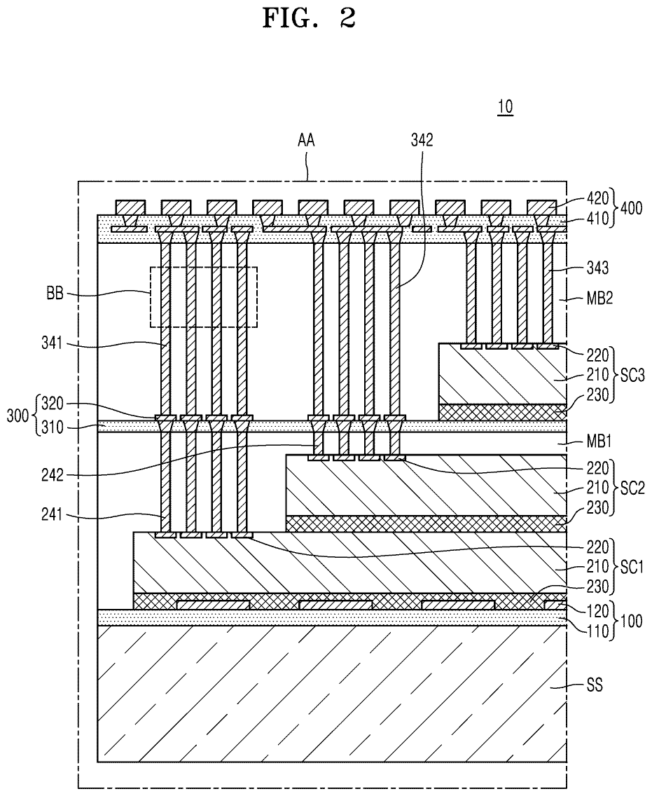

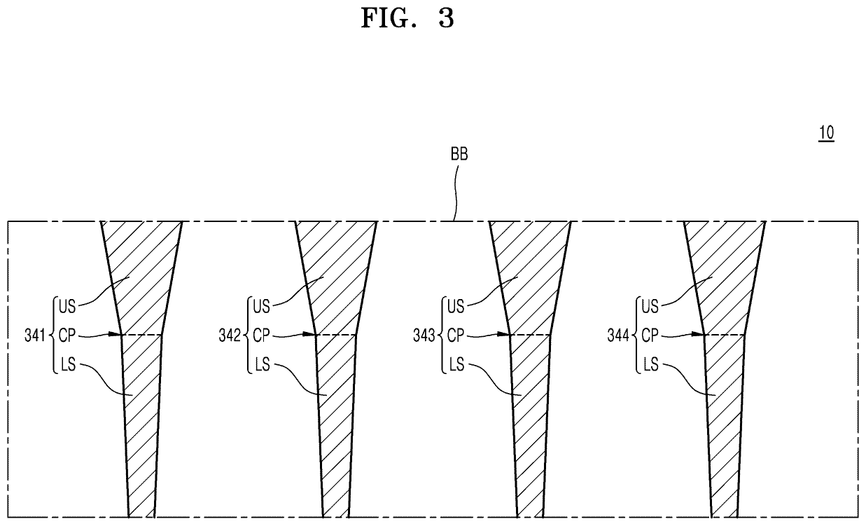

FIG. 1 is a cross-sectional view of a semiconductor package 10 according to one or more implementations. FIG. 2 is an enlarged cross-sectional view of portion AA of FIG. 1. FIG. 3 is an enlarged cross-sectional view of portion BB of FIG. 2.

Referring to FIGS. 1 to 3 together, the semiconductor package 10 according to the implementation may include a package substrate SS, a plurality of semiconductor chips (e.g., SC1, SC2, SC3, and SC4), a plurality of conductive posts (e.g., 241, 242, 341, 342, 343, and 344), a plurality of molding members (e.g., MB1 and MB2), and a plurality of wiring structures (e.g., 100, 300, and 400).

The semiconductor package 10 may include a low power-double data rate (LPDDR) memory.

In a package technique that integrates a plurality of individual devices into a single package, the number of semiconductor chips (e.g., SC1, SC2, SC3, and SC4) may vary depending on the purpose of the semiconductor package 10. Accordingly, the present disclosure is not limited by the number of semiconductor chips (e.g., SC1, SC2, SC3, and SC4).

The package substrate SS may serve as a base substrate, a wiring substrate, and/or an external terminal connection substrate. The package substrate SS may be formed based on a semiconductor substrate, a printed circuit board (PCB), a ceramic substrate, and a glass substrate. In some implementations, the package substrate SS may be an interposer. In other implementations, the package substrate SS may be omitted.

The plurality of wiring structures (e.g., 100, 300, and 400) may include a first wiring structure 100, a second wiring structure 300, and a third wiring structure 400. In some implementations, each of the first wiring structure 100, the second wiring structure 300, and the third wiring structure 400 may be formed using a redistribution process. Accordingly, the first wiring structure 100, the second wiring structure 300, and the third wiring structure 400 may be referred to as a lower redistribution structure, a middle redistribution structure, and an upper redistribution structure, respectively.

The first wiring structure 100 may be formed on the package substrate SS. The first wiring structure 100 may include a first insulating layer 110 and a plurality of first conductive patterns 120. The first insulating layer 110 may surround the plurality of first conductive patterns 120 or be under the plurality of first conductive patterns 120. In some implementations, the first wiring structure 100 may include a plurality of first insulating layers 110 that are stacked.

The plurality of first conductive patterns 120 may include, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof.

A first semiconductor chip SC1 may be mounted on the first wiring structure 100. The first semiconductor chip SC1 may include a semiconductor substrate 210 having an active surface and an inactive surface that are opposite each other. A first surface and a second surface of the first semiconductor chip SC1 may be opposite to each other, and the first surface of the first semiconductor chip SC1 may refer to the active surface of the semiconductor substrate 210. Accordingly, the illustration of distinguishing the active surface of the semiconductor substrate 210 from the first surface of the first semiconductor chip SC1 is omitted.

The first semiconductor chip SC1 may include a semiconductor device (not shown) formed on the active surface of the semiconductor substrate 210 and a plurality of upper connection pads 220 formed on the first surface of the first semiconductor chip SC1. In some implementations, the first semiconductor chip SC1 may be arranged such that the second surface of the first semiconductor chip SC1 faces the first wiring structure 100. The first semiconductor chip SC1 may be mounted over a top surface of the first wiring structure 100 through a die-attach film 230.

The semiconductor substrate 210 may include a semiconductor material, such as silicon (Si) or germanium (Ge). Alternatively, the semiconductor substrate 210 may include a compound semiconductor material, such as silicon carbide (SiC), gallium arsenide (GaAs), InAs (indium arsenide (InAs), and indium phosphide (InP). The semiconductor substrate 210 may include a doped well, which is a conductive region. The semiconductor substrate 210 may have various device isolation structures, such as a shallow trench isolation (STI) structure.

Although not shown, a semiconductor device including a plurality of individual devices of various types may be formed on the active surface of the semiconductor substrate 210. The semiconductor device may be electrically connected to the conductive region of the semiconductor substrate 210. The semiconductor device may further include conductive wirings or conductive plugs configured to electrically connect the plurality of individual devices to the conductive region of the semiconductor substrate 210.

The plurality of upper connection pads 220 may be on an outer region of the first surface of the first semiconductor chip SC1. As described below, the plurality of upper connection pads 220 may be in a region exposed by second through fourth semiconductor chips SC2, SC3, and SC4 stacked on the first semiconductor chip SC1. Accordingly, a plurality of first lower conductive posts 241 may be brought into contact with the plurality of upper connection pads 220 of the first semiconductor chip SC1. The plurality of first lower conductive posts 241 may connect the first semiconductor chip SC1 to the outside.

The die-attach film 230 may be divided into an inorganic adhesive and a polymer adhesive. In the polymer adhesive, a polymer may be divided into thermosetting resins and thermoplastic resins. A thermosetting resin may have a three-dimensional (3D) network structure after a monomer is heat-molded, and may not soften even when reheated. In contrast, a thermoplastic resin may be a resin that exhibits plasticity when heated, and have a linear polymer structure. There are also hybrid-type polymers that are made by mixing thermosetting resin and thermoplastic resin.

The first semiconductor chip SC1 may include a memory device. For example, the memory device may include a non-volatile memory device, such as flash memory, phase-change RAM (PRAM), magnetoresistive RAM (MRAM), ferroelectric RAM (FeRAM), or resistive RAM (RRAM). In some implementations, the memory device may include a volatile memory device, such as dynamic random access memory (DRAM) or static RAM (SRAM).

The second semiconductor chip SC2 may be stacked and mounted on the first semiconductor chip SC1 in a vertical direction (Z direction) and shifted a predetermined distance from an edge of the first semiconductor chip SC1 in a first lateral direction (X direction) to expose the plurality of upper connection pads 220 formed on an outer region of the top surface of the first semiconductor chip SC1.

The second semiconductor chip SC2 may substantially be the same as the first semiconductor chip SC1. Thus, the following description will focus on the differences between the second semiconductor chip SC2 and the first semiconductor chip SC1 described above.

In the second semiconductor chip SC2, the plurality of upper connection pads 220 may be on an outer region of a first surface of the second semiconductor chip SC2. As described below, the plurality of upper connection pads 220 may be in a region exposed by the third and fourth semiconductor chips SC3 and SC4 stacked on the second semiconductor chip SC2. Accordingly, a plurality of second lower conductive posts 242 may be located on and contact the plurality of upper connection pads 220 of the second semiconductor chip SC2. The plurality of second lower conductive posts 242 may connect the second semiconductor chip SC2 to the outside.

A first molding member MB1 may surround the first semiconductor chip SC1 and the second semiconductor chip SC2 on the top surface of the first wiring structure 100. The first molding member MB1 may fill a space between the first wiring structure 100 and the second wiring structure 300. The first molding member MB1 may include, for example, an epoxy mold compound (EMC). In addition, the first molding member MB1 may further include a filler.

The first molding member MB1 may surround the plurality of first and second lower conductive posts 241 and 242. That is, the plurality of first and second lower conductive posts 241 and 242 may pass through the first molding member MB1 and electrically connect the first wiring structure 100 to the second wiring structure 300.

The second wiring structure 300 may be on the first molding member MB1. The second wiring structure 300 may include a second insulating layer 310 and a plurality of second conductive patterns 320. The second insulating layer 310 may surround the plurality of second conductive patterns 320. In some implementations, the second wiring structure 300 may include a plurality of second insulating layers 310 that are stacked.

The plurality of second conductive patterns 320 may be connected to the plurality of first and second lower conductive posts 241 and 242 located under the second wiring structure 300. The plurality of second conductive patterns 320 may be connected to a plurality of first and second upper conductive posts 341 and 342 located on the second wiring structure 300. That is, the first semiconductor chip SC1 may be connected to the outside through the plurality of first lower conductive posts 241 and a plurality of first upper conductive posts 341. Also, the semiconductor chip SC2 may be connected to the outside through the plurality of second lower conductive posts 242 and a plurality of second upper conductive posts 342.

On the second wiring structure 300, the third semiconductor chip SC3 may be stacked and mounted on the second semiconductor chip SC2 in the vertical direction (Z direction) and shifted a predetermined distance from an edge of the second semiconductor chip SC2 in the first lateral direction (X direction) to expose the plurality of upper connection pads 220 formed in an outer region of the top surface of the second semiconductor chip SC2.

The third semiconductor chip SC3 may substantially be the same as the first semiconductor chip SC1. Thus, the following description will focus on the differences between the third semiconductor chip SC3 and the first semiconductor chip SC1 described above.

In the third semiconductor chip SC3, the plurality of upper connection pads 220 may be on an outer region of a first surface of the third semiconductor chip SC3. As described below, the plurality of upper connection pads 220 may be on a region exposed by the fourth semiconductor chip SC4 stacked on the third semiconductor chip SC3. Accordingly, a plurality of third upper conductive posts 343 may be located on and contact the plurality of upper connection pads 220 of the third semiconductor chip SC3. The plurality of third upper conductive posts 343 may connect the third semiconductor chip SC3 to the outside.

The fourth semiconductor chip SC4 may be stacked and mounted on the third semiconductor chip SC3 in the vertical direction (Z direction) and shifted a predetermined distance from an edge of the third semiconductor chip SC3 in the first lateral direction (X direction) to expose the plurality of upper connection pads 220 formed in an outer region of the top surface of the third semiconductor chip SC3.

The fourth semiconductor chip SC4 may substantially be the same as the first semiconductor chip SC1. Thus, the following description will focus on the differences between the fourth semiconductor chip SC4 and the first semiconductor chip SC1 described above.

In the fourth semiconductor chip SC4, the plurality of upper connection pads 220 may be on an outer region of a first surface of the fourth semiconductor chip SC4. A plurality of fourth upper conductive posts 344 may be located on and contact the plurality of upper connection pads 220 of the fourth semiconductor chip SC4. The plurality of fourth upper conductive posts 344 may connect the fourth semiconductor chip SC4 to the outside.

A second molding member MB2 may surround the third semiconductor chip SC3 and the fourth semiconductor chip SC4 on a top surface of the second wiring structure 300. The second molding member MB2 may fill a space between the second wiring structure 300 and the third wiring structure 400. The second molding member MB2 may substantially include the same material as the first molding member MB1.

The second molding member MB2 may surround a plurality of first to fourth upper conductive posts 341, 342, 343, and 344. That is, the plurality of first to fourth upper conductive posts 341, 342, 343, and 344 may pass through the second molding member MB2 and electrically connect the second wiring structure 300 to the third wiring structure 400.

The third wiring structure 400 may be formed on the second molding member MB2. The third wiring structure 400 may include a third insulating layer 410 and a plurality of third conductive patterns 420. The third insulating layer 410 may surround the plurality of third conductive patterns 420. In some implementations, the third wiring structure 400 may include a plurality of third insulating layers 410 that are stacked.

The plurality of third conductive patterns 420 may be connected to the plurality of first to fourth upper conductive posts 341, 342, 343, and 344 located under the third wiring structure 400. That is, the first semiconductor chip SC1 may be connected to the outside through the plurality of first lower conductive posts 241 and the plurality of first upper conductive posts 341. Also, the second semiconductor chip SC2 may be connected to the outside through the plurality of second lower conductive posts 242 and the plurality of second upper conductive posts 342. In addition, the third semiconductor chip SC3 may be connected to the outside through the plurality of third upper conductive posts 343. Furthermore, the fourth semiconductor chip SC4 may be connected to the outside through the plurality of fourth upper conductive posts 344.

A length of each of the plurality of first and second upper conductive posts 341 and 342 in the vertical direction (Z direction) may be in a range of about 100 μm to about 1000 μm. In addition, an aspect ratio (i.e., a ratio of height to lateral width) of each of the plurality of first and second upper conductive posts 341 and 342 may be higher than about 8.

In some implementations, each of the plurality of first upper conductive posts 341 may include a lower portion LS and an upper portion US. In each of the plurality of first upper conductive posts 341, a slope of a sidewall may be changed at an interface CP between the lower portion LS and the upper portion US. Here, the lower portion LS and the upper portion US arc simply divisions to explain the above-described features, and each of the plurality of first upper conductive posts 341 may constitute one body. Also, the slope of the sidewall shown in FIG. 3 is an example, and the present disclosure is not limited thereto.

In general, to form a conductive post, exposure and development processes using photoresist may be employed. Recently, as the height of conductive posts is rapidly increasing, the thickness of photoresist must also be increased. However, when the photoresist has a predetermined thickness or more, the resolution (or light transmittance) of the photoresist may be significantly reduced. Thus, it may be difficult to manufacture a conductive post that satisfies an increased height by using a single exposure process and a single development process and a single plating process corresponding thereto.

As a result, to manufacture a conductive post with an increased height, a process of manufacturing the conductive post is being divided into at least two processes. That is, two exposure processes and two development processes and a double plating process corresponding thereto are being used. In this case, however, a considerable number of additional process operations may be needed to lower productivity.

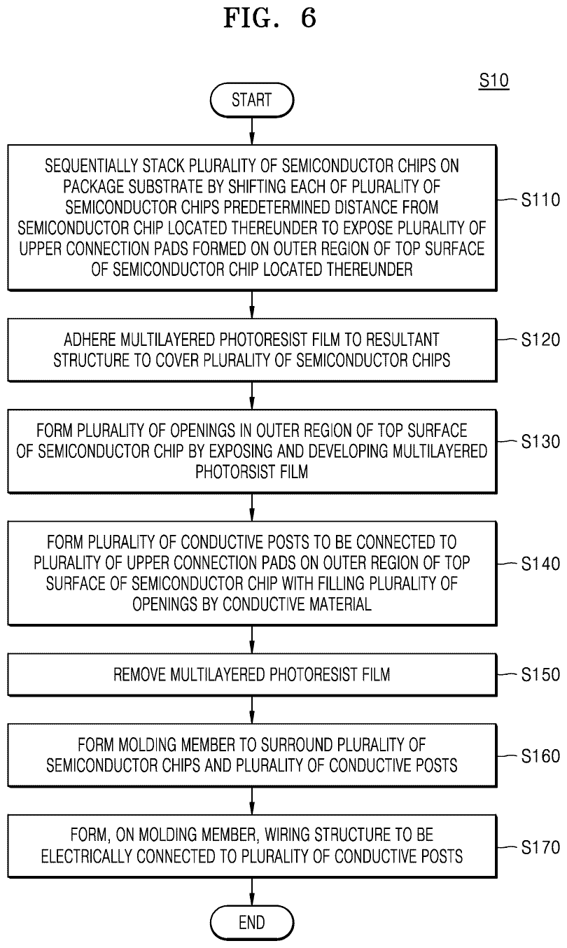

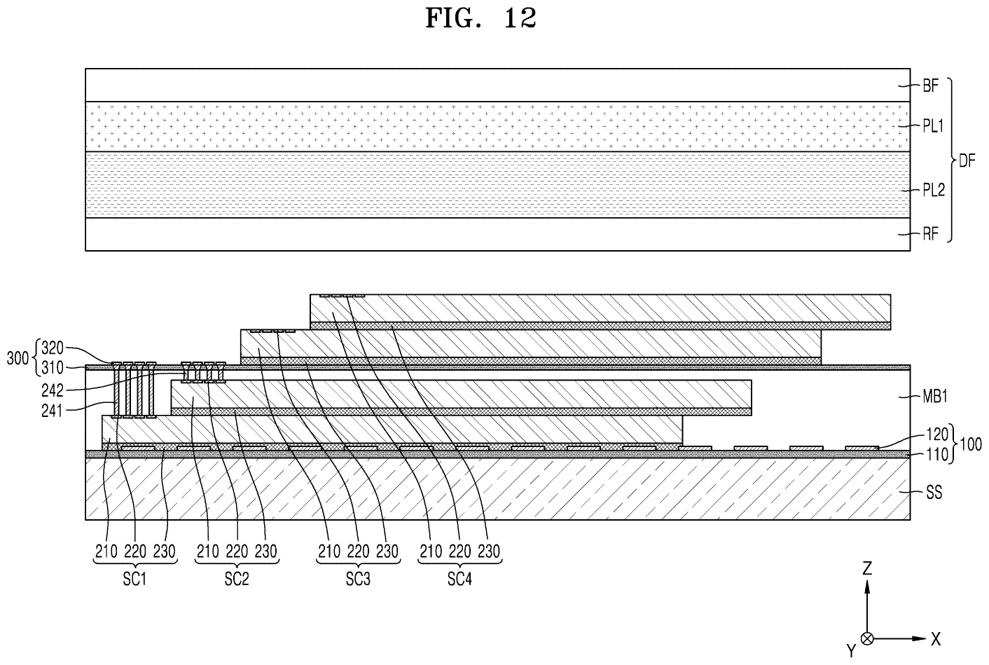

To solve the above-described problem, as in a method (refer to S10 in FIG. 6) of manufacturing a semiconductor package, which is described below, in the semiconductor package 10 according to the present disclosure, by using a multilayered photoresist film (refer to DF in FIG. 12) in which respective layers have different properties, the plurality of first and second conductive posts 341 and 342 having a relatively high aspect ratio (e.g., an aspect ratio of 8 or higher) may be accurately formed according to design rules by using a single exposure process and a single development process and a single plating process corresponding thereto.

In conclusion, according to a method (refer to S10 in FIG. 6) of manufacturing a semiconductor package by using a multilayered photoresist film (refer to DF in FIG. 12), the reliability and productivity of the semiconductor package 10 may improve.

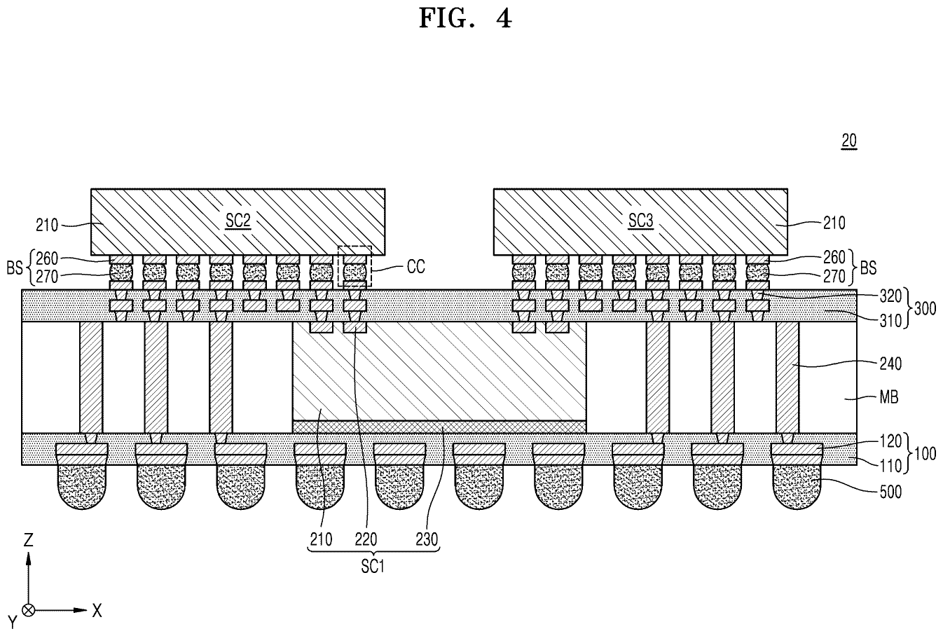

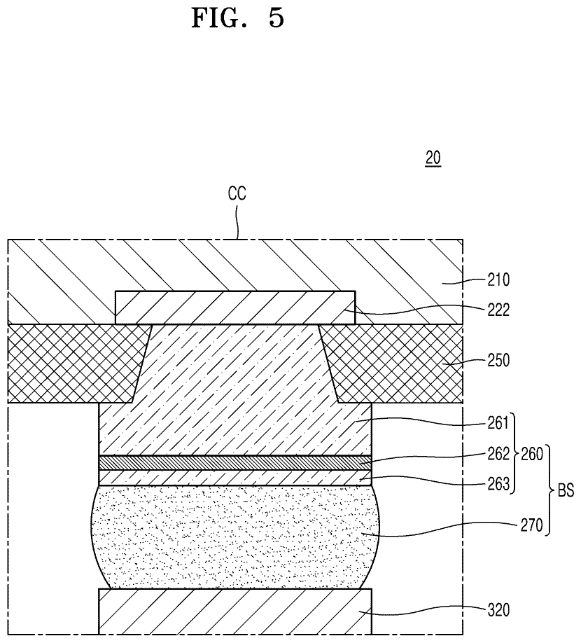

FIG. 4 is a cross-sectional view of a semiconductor package 20 according to one or more implementations. FIG. 5 is an enlarged cross-sectional view of portion CC of FIG. 4.

Most of components included in the semiconductor package 20 described below and materials included in the components may substantially be the same as or similar to those described above with reference to FIGS. 1 to 3. Thus, for brevity, the following description will focus on the differences between the semiconductor package 20 and the semiconductor package 10 described above.

Referring to FIGS. 4 and 5 together, the semiconductor package 20 according to the present implementation may include a plurality of semiconductor chips (e.g., SC1, SC2, and SC3), a plurality of conductive posts 240, a plurality of bump structures BS, a molding member MB, a plurality of wiring structures (e.g., 100 and 300), and a plurality of external connection terminals 500.

The semiconductor package 20 may be a fan-out semiconductor package in which a total lateral width and a total horizontal area of the plurality of wiring structures (e.g., 100 and 300) are greater than a total lateral width and a total horizontal area of the plurality of semiconductor chips (e.g., SC1, SC2, and SC3).

The plurality of wiring structures (e.g., 100 and 300) may include a first wiring structure 100 and a second wiring structure 300. In some implementations, each of the first wiring structure 100 and the second wiring structure 300 may be formed using a redistribution process. Accordingly, the first wiring structure 100 and the second wiring structure 300 may be respectively referred to as a lower redistribution structure and an upper redistribution structure.

The first wiring structure 100 may include a first insulating layer 110 and a plurality of first conductive patterns 120. The first insulating layer 110 may surround the plurality of first conductive patterns 120 or be under the plurality of first conductive patterns 120. In some implementations, the first wiring structure 100 may include a plurality of first insulating layers 110 that are stacked.

A plurality of external connection terminals 500 may be adhered under the plurality of first conductive patterns 120. The plurality of external connection terminals 500 may connect the semiconductor package 20 to the outside. In some implementations, the plurality of external connection terminals 500 may be solder bumps or solder balls.

A first semiconductor chip SC1 may be mounted on the first wiring structure 100. The first semiconductor chip SC1 may include a semiconductor substrate 210 having an active surface and an inactive surface that are opposite each other. A first surface and a second surface of the first semiconductor chip SC1 may be opposite to each other, and the first surface of the first semiconductor chip SC1 may refer to the active surface of the semiconductor substrate 210.

The first semiconductor chip SC1 may include a semiconductor device (not shown) formed on the active surface of the semiconductor substrate 210 and a plurality of upper connection pads 220 formed on the first surface of the first semiconductor chip SC1. In some implementations, the first semiconductor chip SC1 may be arranged such that the second surface of the first semiconductor chip SC1 faces the first wiring structure 100. The first semiconductor chip SC1 may be mounted over a top surface of the first wiring structure 100 through a die-attach film 230.

The plurality of upper connection pads 220 may be on an outer region of the first surface of the first semiconductor chip SC1. As described below, the plurality of upper connection pads 220 may contact the plurality of second conductive patterns 320.

The first semiconductor chip SC1 may include a logic device. For example, the first semiconductor chip SC1 may be a central processing unit (CPU) chip, a graphics processing unit (GPU) chip, or an application processor (AP) chip.

The plurality of conductive posts 240 may be apart from the first semiconductor chip SC1 in a lateral direction (X and Y directions) and located around the first semiconductor chip SC1.

The molding member MB may surround the first semiconductor chip SC1 on the top surface of the first wiring structure 100. The molding member MB may fill a space between the first wiring structure 100 and the second wiring structure 300. For example, the molding member MB may include an EMC. Also, the molding member MB may further include a filler.

The molding member MB may surround the plurality of conductive posts 240. That is, the plurality of conductive posts 240 may pass through the molding member MB and electrically connect the first wiring structure 100 to the second wiring structure 300.

The second wiring structure 300 may be on the molding member MB and the first semiconductor chip SC1. The second wiring structure 300 may include a second insulating layer 310 and a plurality of second conductive patterns 320. The second insulating layer 310 may surround the plurality of second conductive patterns 320. In some implementations, the second wiring structure 300 may include a plurality of second insulating layers 310 that are stacked.

Second and third semiconductor chips SC2 and SC3 may be arranged in a line on the second wiring structure 300 in a first lateral direction (X direction).

The second and third semiconductor chips SC2 and SC3 may substantially be the same as each other. Thus, the following description will focus on the second semiconductor chip SC2.

A plurality of bump structures BS may be formed under a plurality of electrode pads 222 located under the semiconductor substrate 210 of the second semiconductor chip SC2. The plurality of bump structures BS may include a plurality of bump pads 260 and a plurality of solder bumps 270. The plurality of solder bumps 270 may be formed under the plurality of bump pads 260. The plurality of bump structures BS may electrically connect the second semiconductor chip SC2 to the second wiring structure 300.

The second semiconductor chip SC2 may include a memory device. For instance, the memory device may be a non-volatile memory device, such as flash memory, PRAM, MRAM, FeRAM, or RRAM. In some implementations, the memory device may be a volatile memory device, such as DRAM or SRAM.

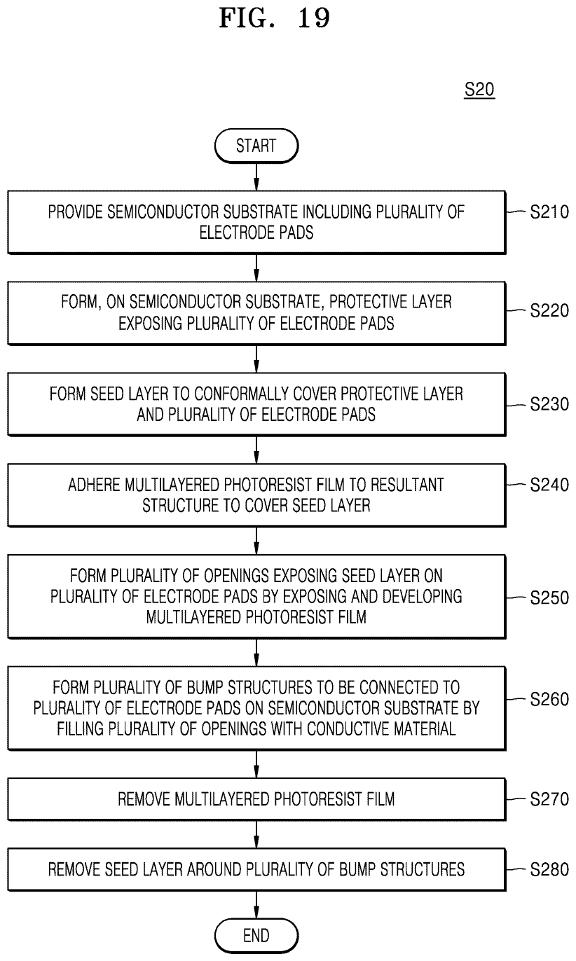

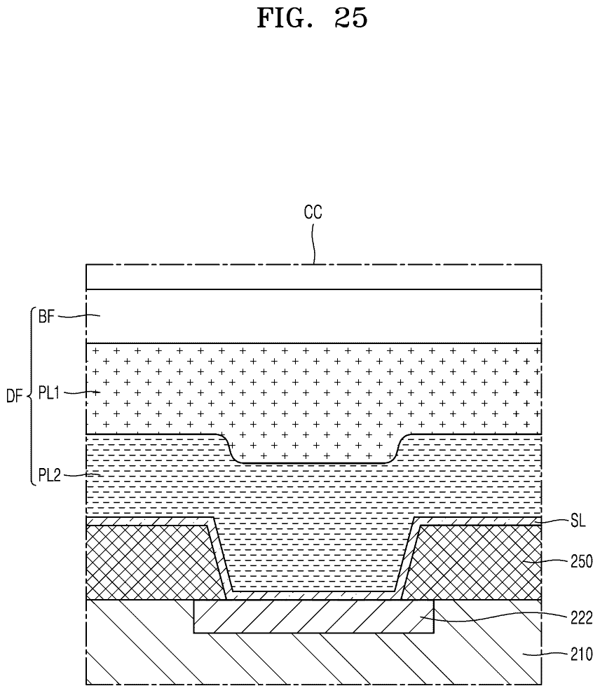

As in a method (refer to S20 in FIG. 19) of manufacturing a semiconductor package, which is described below, in the semiconductor package 20 according to the present disclosure, by using a multilayered photoresist film (refer to DF in FIG. 25) in which respective layers have different properties, the plurality of bump structures BS having a relatively high aspect ratio may be accurately formed according to design rules by using a single exposure process and a single development process and a single plating process corresponding thereto.

In conclusion, according to a method (refer to S20 in FIG. 19) of manufacturing a semiconductor package by using a multilayered photoresist film (refer to DF in FIG. 25), the reliability and productivity of the semiconductor package 20 may improve.

FIG. 6 is a flowchart of a method of manufacturing a semiconductor package, according to one or more implementations.

Referring to FIG. 6, a method S10 of manufacturing a semiconductor package may include a process sequence of first to seventh operations S110 to S170.

When some implementations may be embodied otherwise, respective process steps described herein may be performed otherwise. For example, two process steps described in a sequential order may be performed substantially at the same time or in reverse order.

The method S10 of manufacturing a semiconductor package, according to the present disclosure, may include a first operation S110 of sequentially stacking a plurality of semiconductor chips on a package substrate while shifting each of the plurality of semiconductor chips a predetermined distance from an edge of a semiconductor chip thereunder in a lateral direction to expose a plurality of upper connection pads formed in an outer region of a top surface of the semiconductor chip located thereunder, a second operation S120 of adhering a multilayered photoresist film to the resultant structure to cover the plurality of semiconductor chips, a third operation S130 of forming a plurality of openings in an outer region of a top surface of a semiconductor chip by exposing and developing the multilayered photoresist film, a fourth operation S140 of forming a plurality of conductive posts to be connected to the plurality of upper connection pads on the outer region of the top surface of the semiconductor chip by filling the plurality of openings with a conductive material, a fifth operation S150 of removing the multilayered photoresist film, a sixth operation S160 of forming a molding member surrounding the plurality of semiconductor chips and the plurality of conductive posts, and a seventh operation S170 of forming, on the molding member, a wiring structure to be electrically connected to the plurality of conductive posts.

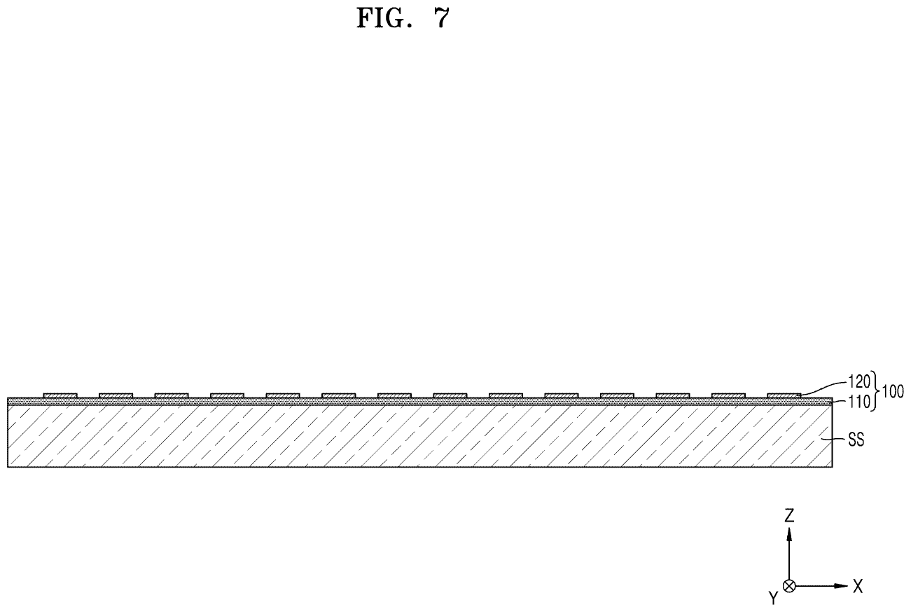

Technical characteristics of each of the first to seventh operations S110 to S170 are described in detail below with reference to FIGS. 7 to 18.

FIGS. 7 to 18 are cross-sectional views of a process sequence of a method of manufacturing a semiconductor package, according to one or more implementations.

Referring to FIG. 7, a first wiring structure 100 including a first insulating layer 110 and a plurality of first conductive patterns 120 may be formed on a package substrate SS.

The package substrate SS may be formed based on a semiconductor substrate, a PCB, a ceramic substrate, and a glass substrate. In some implementations, a release film may be adhered onto the package substrate SS, and the first wiring structure 100 may be formed on the release film.

In some implementations, the plurality of first conductive patterns 120 may include a conductive layer formed on a top surface of the first insulating layer 110.

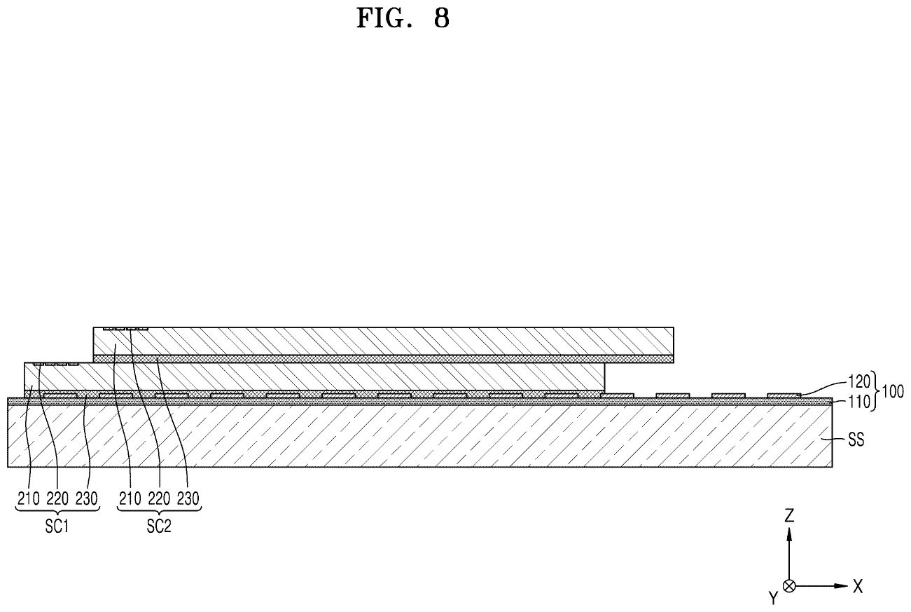

Referring to FIG. 8, first and second semiconductor chips SC1 and SC2 may be sequentially mounted on the first wiring structure 100.

Each of the first and second semiconductor chips SC1 and SC2 may be stacked on the package substrate SS and shifted a predetermined distance from an edge of a semiconductor chip located thereunder in a first lateral direction (X direction) to expose a plurality of upper connection pads 220 formed in a portion of a top surface of a semiconductor chip (e.g., the first semiconductor chip SC1) located thereunder. The mounting process may be performed by using a die-attach film 230 adhered to a bottom surface of each of the first and second semiconductor chips SC1 and SC2.

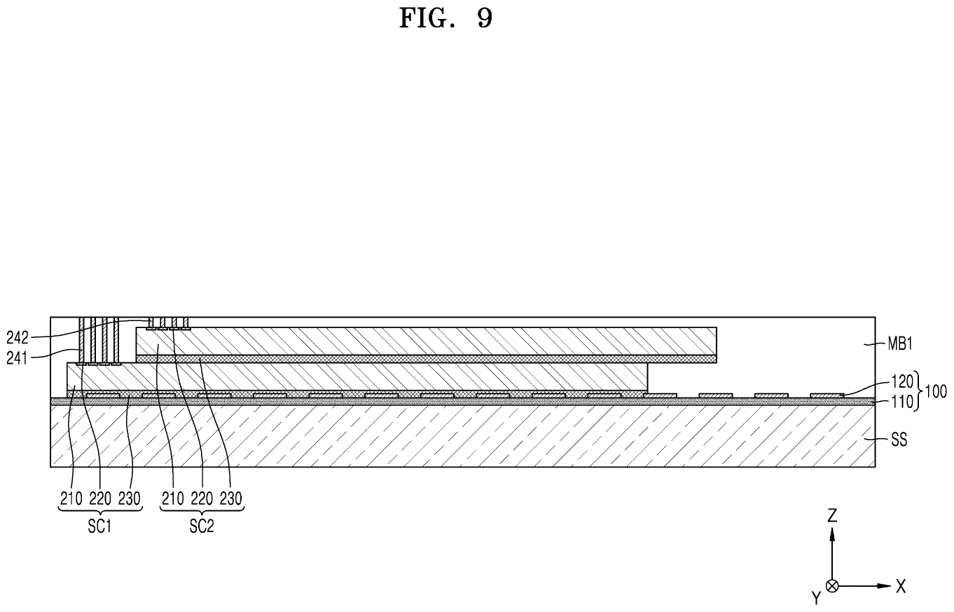

Referring to FIG. 9, a plurality of first and second lower conductive posts 241 and 242 may be formed at the first and second semiconductor chips SC1 and SC2.

The formation of the plurality of first and second lower conductive posts 241 and 242 may include forming a photomask by using an exposure process and a development process and preparing conductive posts by using a plating process.

Next, a first molding member MB1 may be formed to cover the package substrate SS and the first and second semiconductor chips SC1 and SC2 and expose top surfaces of the plurality of first and second lower conductive posts 241 and 242.

The first molding member MB1 may be formed on a top surface of the package substrate SS to surround the first and second semiconductor chips SC1 and SC2 and the plurality of first and second lower conductive posts 241 and 242 and protect the first and second semiconductor chips SC1 and SC2 and the plurality of first and second lower conductive posts 241 and 242 from the external environment.

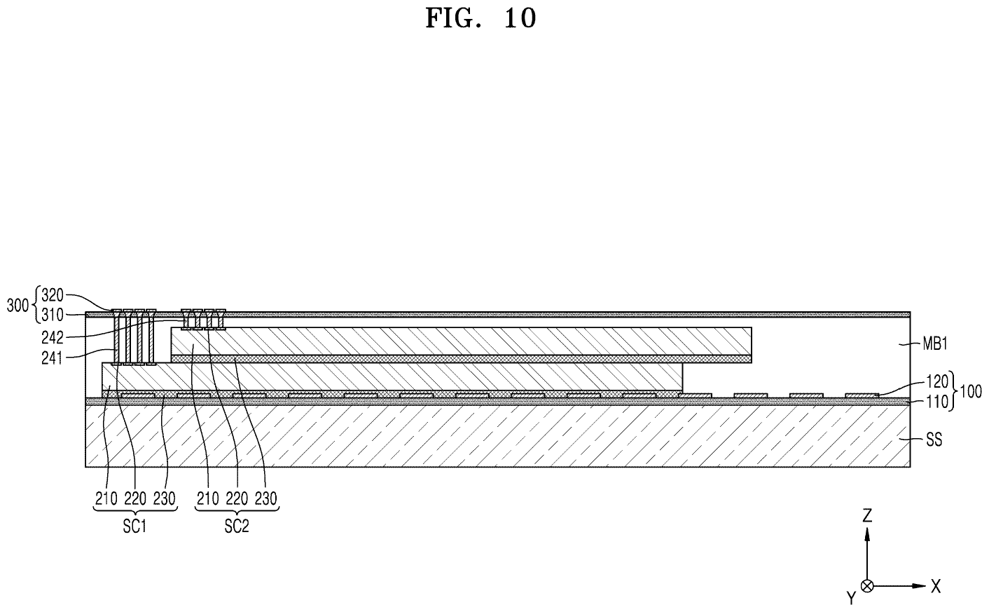

Referring to FIG. 10, a second wiring structure 300 including a second insulating layer 310 and a plurality of second conductive patterns 320 may be formed on the first molding member MB1 and the plurality of first and second lower conductive posts 241 and 242.

In the second wiring structure 300, the second insulating layer 310 may be formed to surround the plurality of second conductive patterns 320. In some implementations, the second wiring structure 300 may include a plurality of second insulating layers 310 that are stacked.

The plurality of second conductive patterns 320 may be connected to the plurality of first and second lower conductive posts 241 and 242 located under the second wiring structure 300.

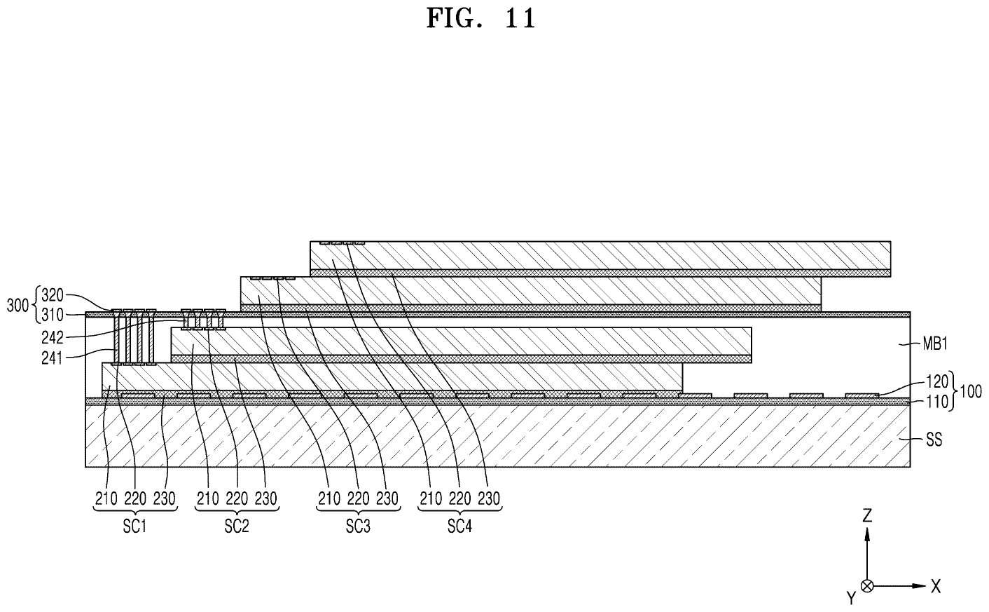

Referring to FIG. 11, third and fourth semiconductor chips SC3 and SC4 may be sequentially mounted on the second wiring structure 300.

Each of the third and fourth semiconductor chips SC3 and SC4 may be stacked on the second wiring structure 300 and shifted a predetermined distance from an edge of a semiconductor chip located thereunder in the first lateral direction (X direction) to expose the plurality of upper connection pads 220 formed on a portion of a tip surface of a semiconductor chip located thereunder (e.g., the third semiconductor chip SC3) and the plurality of second conductive patterns 320 connected to the plurality of first and second lower conductive posts 241 and 242. The mounting process may be performed using a die-attach film 230 adhered to a bottom surface of each of the third and fourth semiconductor chips SC3 and SC4.

Referring to FIG. 12, a dry resist film DF may be provided to be used as a photomask.

The dry resist film DF may include a release film RF, a first photoresist layer PL1, a second photoresist layer PL2, and a base film BF.

Specifically, a process of forming the dry resist film DF is now described. To begin with, the first photoresist layer PL1 may be formed on the base film BF. Although not shown, the second photoresist layer PL2 may be formed on a second base film. Next, the base film BF may be combined with the second base film such that the first photoresist layer PL1 is in contact with the second photoresist layer PL2. Thereafter, the second base film may be removed from the second photoresist layer PL2, and the release film RF may be adhered to the second photoresist layer PL2.

The base film BF may serve as a support film and an upper protective film to protect a top surface of the first photoresist layer PL1 and include, for example, polyolefin (PO), polyethylene terephthalate (PET), polyetheretherketone (PEEK), and polyimide (PI), without being limited thereto. The base film BF may be provided to a thickness of, for example, about 5 micrometer (μm) to about 100 μm.

The release film RF may serve as a lower protective film to protect a bottom surface of the second photoresist layer PL2 and include, for example, PO, PET, PEEK, and PI, without being limited thereto. The release film RF may be provided to a thickness of, for example, about 5 μm to about 100 μm.

In some implementations, the first photoresist layer PL1 and the second photoresist layer PL2 may include negative photoresist. In general, in negative photoresist used in negative tone development, a polymer including a chemically amplified photoresist material may be used as a main polymer, an exposed portion (i.e., a portion irradiated with light exceeding a threshold amount of light) may remain, an unexposed portion (i.e., a portion not irradiated with light exceeding the threshold amount of light) may be removed by a solvent.

For instance, a molecular weight of a first main polymer included in the first photoresist layer PL1 may be greater than a molecular weight of a second main polymer included in the second photoresist layer PL2. That is, the molecular weight of the first main polymer may be in a range of about 150 percent (%) to about 1000% of the molecular weight of the second main polymer.

For example, a —C═C content of the first main polymer may be in a range of about 150% to about 1000% of a C═C content of the second main polymer. In addition, —OH and —COOH contents of the first main polymer may be respectively in a range of about 10% to about 70% of-OH and —COOH contents of the second main polymer.

The first photoresist layer PL1 may be hydrophobic, and the second photoresist layer PL2 may be hydrophilic. That is, a water contact angle of the first main polymer may be in a range of about 110% to about 300% of a water contact angle of the second main polymer.

In some other implementations, the first photoresist layer PL1 and the second photoresist layer PL2 may include positive photoresist. In general, the positive photoresist may include a photosensitive polymer having an acid-labile group, a potential acid, and a solvent. For example, the photosensitive polymer may include a (meth)acrylate polymer. The (meth)acrylate polymer may include an aliphatic (meth)acrylate polymer. Also, the photosensitive polymer may be substituted with various acid-labile protecting groups.

For example, a first molecular weight of polyhydroxystyrene (PHS) included in the first photoresist layer PL1 may be greater than a second molecular weight of PHS included in the second photoresist layer PL2. That is, the first molecular weight may be in a range of about 150% to about 1000% of the second molecular weight.

For example, a first addition amount of a photo active compound (PAC) included in the first photoresist layer PL1 may be smaller than a second addition amount of a PAC included in the second photoresist layer PL2. That is, the first addition amount may be in a range of about 10% to about 70% of the second addition amount. Also, a multi-functional group of the PAC included in the first photoresist layer PL1 may be in a range of about 10% to about 70% of a multi-functional group of the PAC included in the second photoresist layer PL2.

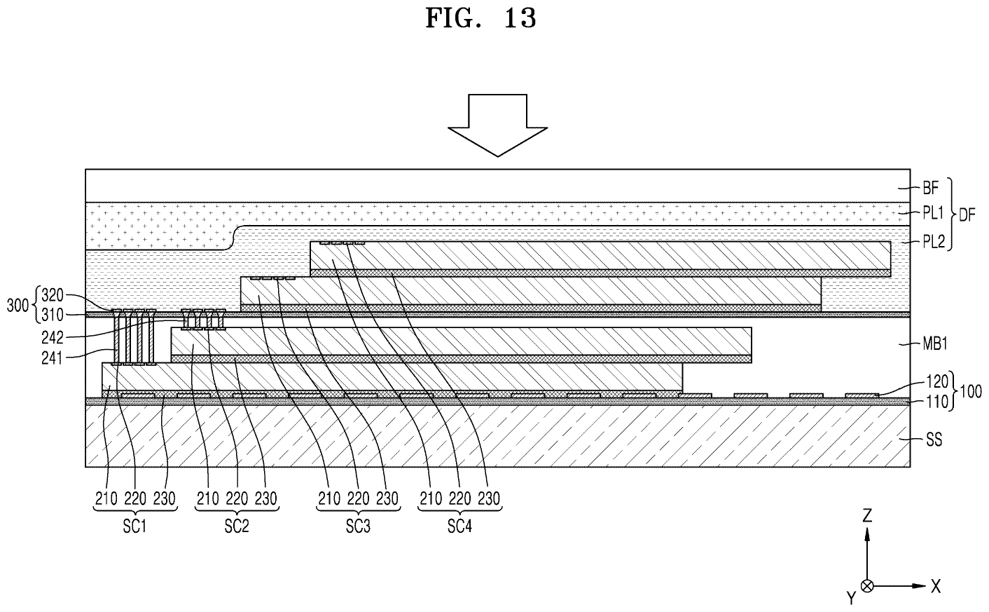

Referring to FIG. 13, the release film (refer to RF in FIG. 12) may be removed from the dry resist film DF, and the second photoresist layer PL2 may be adhered to the resultant structure such that the bottom surface of the second photoresist layer PL2 covers the third and fourth semiconductor chips SC3 and SC4.

The second photoresist layer PL2 may entirely cover exposed portions of the third and fourth semiconductor chips SC3 and SC4 and a top surface of the second wiring structure 300. Also, the second photoresist layer PL2 may be conformally modified along steps of the third and fourth semiconductor chips SC3 and SC4.

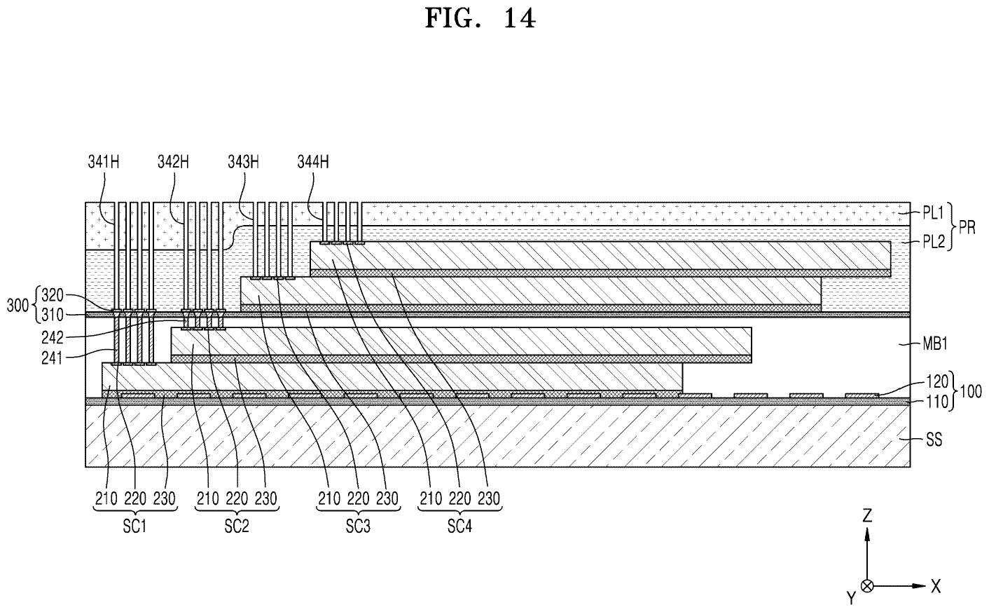

Referring to FIG. 14, the base film (refer to BF in FIG. 13) may be removed from the dry resist film (refer to DF in FIG. 13), and a multilayered photoresist film PR may be exposed and developed. Thus, a plurality of openings 341H, 342H, 343H, and 344H may be formed in an outer region of the second wiring structure 300 and outer regions of the third and fourth semiconductor chips SC3 and SC4.

By performing a single exposure process and a single development process, a plurality of first and second openings 341H and 342H having a high aspect ratio may be regularly formed in the outer region of the second wiring structure 300.

In the method of manufacturing a semiconductor package, according to the present disclosure, to improve a phenomenon where a width of the plurality of first and second openings 341H and 342H having a high aspect ratio becomes excessively greater or less than an intended width, an exposure process and a development process may be performed by using the multilayered photoresist film PR.

By adjusting contents of polymers and/or additives included in the first and second photoresist layers PL1 and PL2 that constitute the multilayered photoresist film PR, chemical resistances and resolutions of the multilayered photoresist film PR may be adjusted.

In some implementations, the first photoresist layer PL1 may have a first chemical resistance and a first resolution, and the second photoresist layer PL2 may have a second chemical resistance and a second resolution. Here, the first chemical resistance may be set to be higher than the second chemical resistance, and the first resolution may be set to be lower than the second resolution.

In the above-described manner, in the multilayered photoresist film PR, the first photoresist layer PL1 located at an upper side may be free from or have less defects, such as cracks, because the first photoresist layer PL1 has high chemical resistance and shrinkage resistance, while the second photoresist layer PL2 located at a lower side may have a high resolution, and thus, a high-resolution environment may be implemented in which a predetermined amount of light or more may be transmitted to a lower portion of the multilayered photoresist film PR.

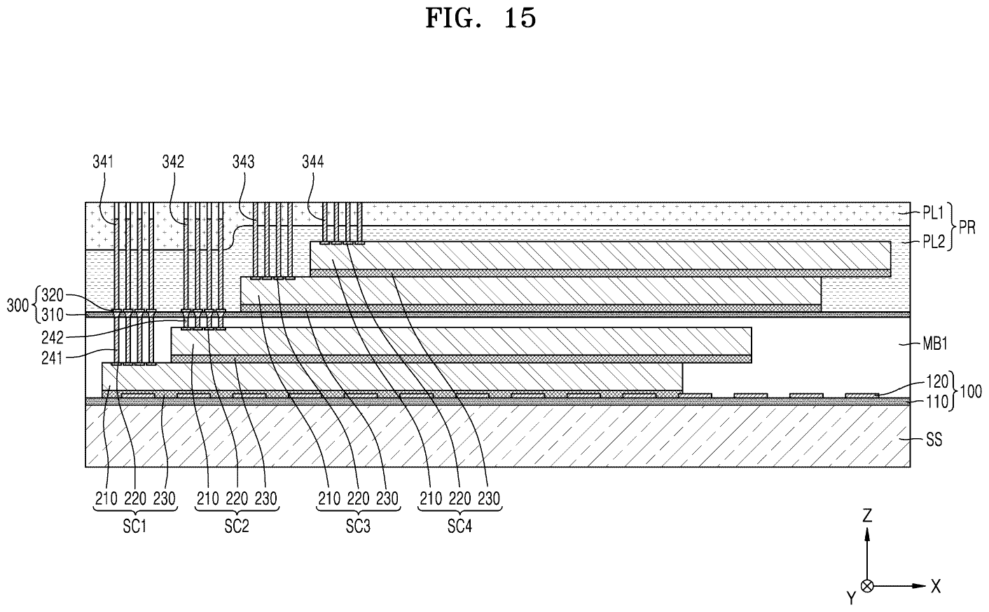

Referring to FIG. 15, the plurality of openings 341H, 342H, 343H, and 344H may be filled by a conductive material, and thus, a plurality of first to fourth upper conductive posts 341, 342, 343, 344 may be formed on the second wiring structure 300 and the third and fourth semiconductor chips SC3 and SC4.

The plurality of first to fourth upper conductive posts 341, 342, 343, and 344 may be formed using a plating process. According to the present disclosure, the plurality of first to fourth upper conductive posts 341, 342, 343, and 344 that satisfy a desired shape may be formed by performing a single exposure process and a single development process using the multilayered photoresist film PR and performing a single plating process corresponding thereto. In some implementations, the plating process may be performed using copper (Cu) or a copper (Cu) alloy, without being limited thereto.

In this case, by differently adjusting the resolutions of the first and second photoresist layers PL1 and PL2 that constitute the multilayered photoresist film PR, a slope of a sidewall may be changed in each of the plurality of first and second upper conductive posts 341 and 342 having a relatively high aspect ratio. Details thereof are the same as described with reference to FIG. 3.

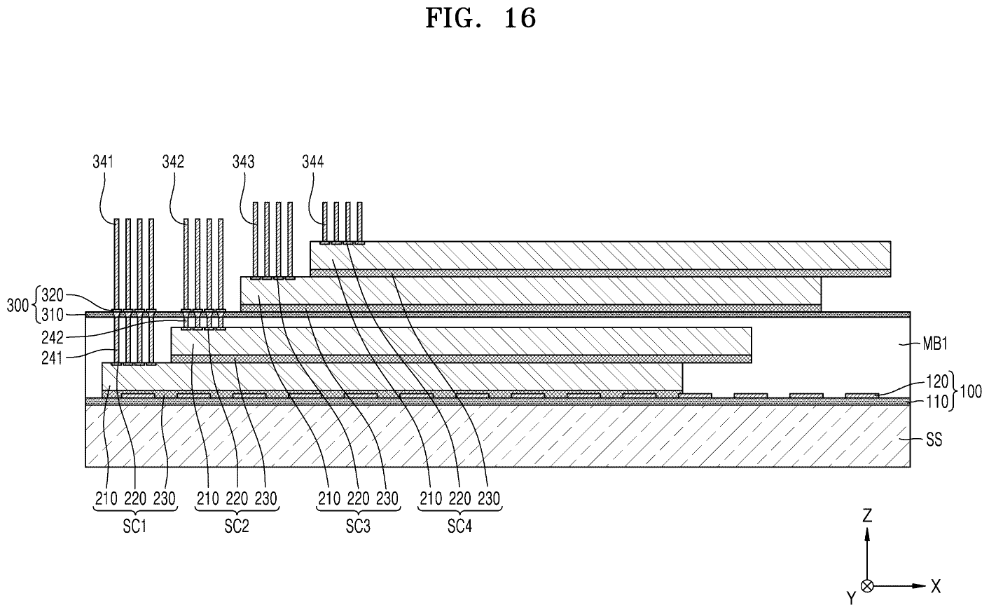

Referring to FIG. 16, the multilayered photoresist film (refer to PR in FIG. 15) may be completely removed.

The multilayered photoresist film (refer to PR in FIG. 15) may be removed using a strip process and/or an ashing process. By removing the multilayered photoresist film (refer to PR in FIG. 15), the third and fourth semiconductor chips SC3 and SC4 and the plurality of first to fourth upper conductive posts 341, 342, 343, and 344 may be exposed to the outside.

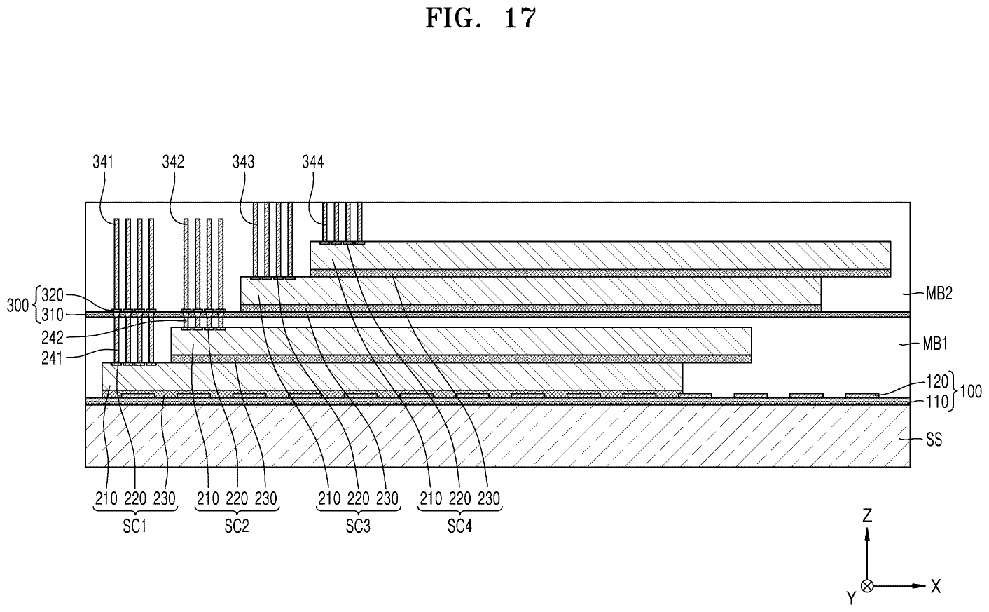

Referring to FIG. 17, a second molding member MB2 may be formed to cover the second wiring structure 300, the third and fourth semiconductor chips SC3 and SC4, and the plurality of first and second upper conductive posts 341 and 342.

The second molding member MB2 may be formed on the top surface of the second wiring structure 300 to surround the third and fourth semiconductor chips SC3 and SC4 and the plurality of first to fourth upper conductive posts 341, 342, 343, and 344 and protect the third and fourth semiconductor chips SC3 and SC4 and the plurality of first to fourth upper conductive posts 341, 342, 343, and 344 from the external environment.

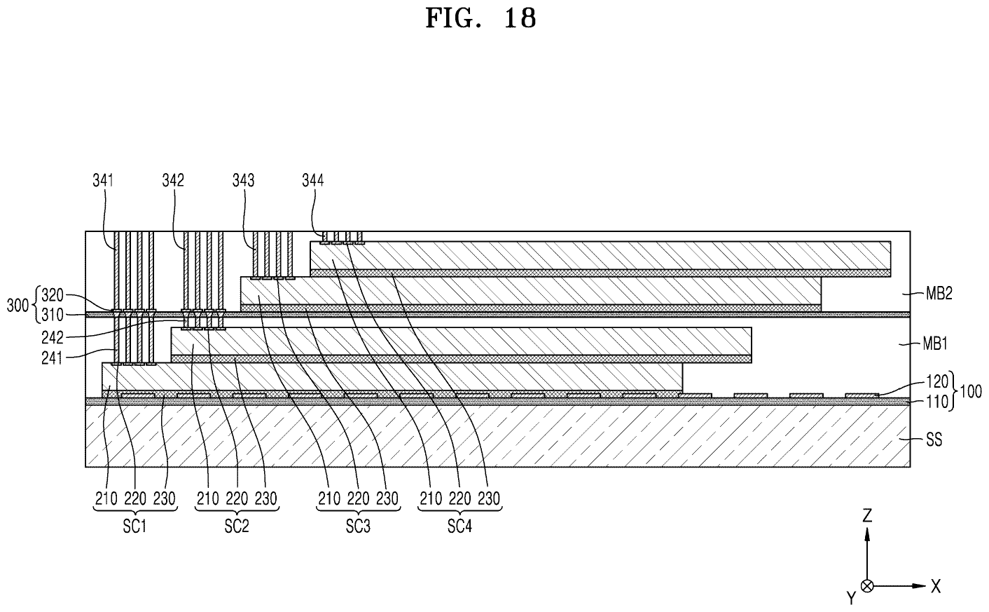

Referring to FIG. 18, a portion of the second molding member MB2 may be removed to entirely expose top surfaces of the plurality of first and second upper conductive posts 341 and 342.

That is, an upper portion of the second molding member MB2 may be removed using a chemical mechanical polishing (CMP) process. Accordingly, upper portions of the plurality of first to fourth upper conductive posts 341, 342, 343, and 344 located in the upper portion of the second molding member MB2 may also be removed together, and thus, the second molding member MB2 may have a planar top surface.

Referring back to FIG. 1, a third wiring structure 400 may be formed on the second molding member MB2. The third wiring structure 400 may include a third insulating layer 410 and a plurality of third conductive patterns 420.

The plurality of third conductive patterns 420 may be connected to the plurality of first to fourth upper conductive posts 341, 342, 343, and 344 located under the third wiring structure 400. That is, the first semiconductor chip SC1 may be connected to the outside through the plurality of first lower conductive posts 241 and the plurality of first upper conductive posts 341. Also, the second semiconductor chip SC2 may be connected to the outside through the plurality of second lower conductive posts 242 and the plurality of second upper conductive posts 342. In addition, the third semiconductor chip SC3 may be connected to the outside through the plurality of third upper conductive posts 343. Furthermore, the fourth semiconductor chip SC4 may be connected to the outside through the plurality of fourth upper conductive posts 344.

By using the method of manufacturing a semiconductor package as described above, the semiconductor package 10 according to the present disclosure may be manufactured.

FIG. 19 is a flowchart of a method of manufacturing a semiconductor package, according to one or more implementations.

Referring to FIG. 19, a method S20 of manufacturing a semiconductor package may include a process sequence of first to eighth operations S210 to S280.

When some implementations may be embodied otherwise, respective process steps described herein may be performed otherwise. For example, two process steps described in a sequential order may be performed substantially at the same time or in reverse order.

The method S20 of manufacturing a semiconductor package, according to the implementation, may include a first operation S210 of providing a semiconductor substrate including a plurality of electrode pads, a second operation S220 of forming, on the semiconductor substrate, a protective layer exposing the plurality of electrode pads, a third operation S230 of forming a seed layer to conformally cover the protective layer and the plurality of electrode pads, a fourth operation S240 of adhering a multilayered photoresist film to the resultant structure to cover the seed layer, a fifth operation S250 of forming a plurality of openings exposing the seed layer on the plurality of electrode pads by exposing and developing the multilayered photoresist film, a sixth operation S260 of forming a plurality of bump structures to be connected to the plurality of electrode pads on the semiconductor substrate by filling the plurality of openings with a conductive material, a seventh operation S270 of removing the multilayered photoresist film, and an eighth operation S280 of removing the seed layer around the plurality of bump structures.

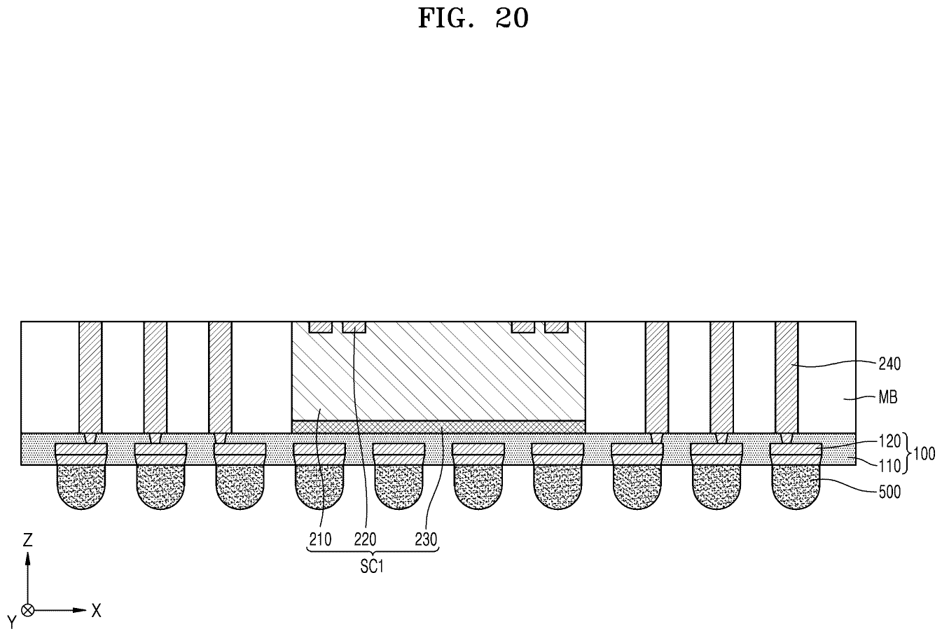

Technical characteristics of each of the first to eighth operations S210 to S280 are described in detail below with reference to FIGS. 20 to 31.

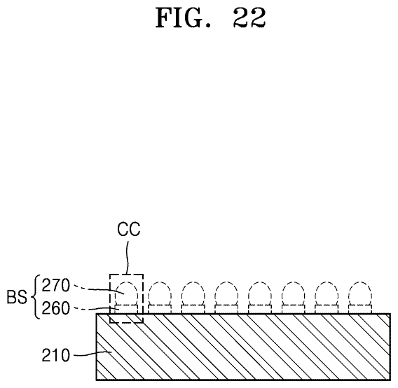

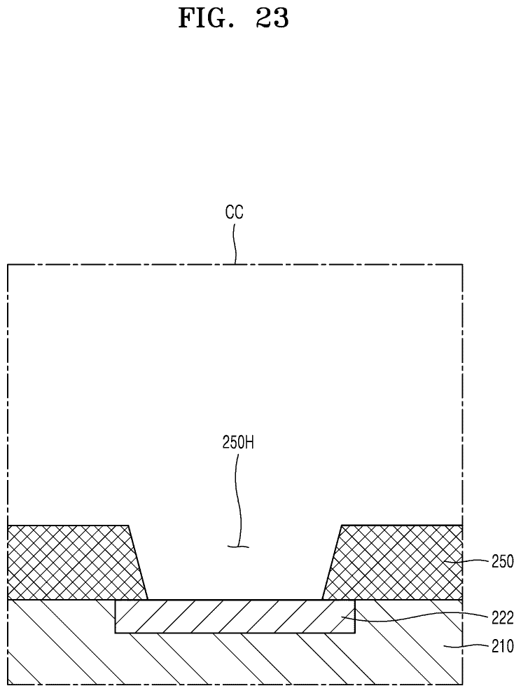

FIGS. 20 to 31 are cross-sectional views of a process sequence of a method of manufacturing a semiconductor package, according to one or more implementations. FIGS. 23 to 30 are enlarged cross-sectional views corresponding to portion CC of FIG. 22.

Referring to FIG. 20, a first semiconductor chip SC1 may be mounted on a first wiring structure 100.

The first semiconductor chip SC1 may be mounted on a chip mounting area of the first wiring structure 100 and apart from a plurality of conductive posts 240 in a lateral direction (X and Y directions).

Next, a molding member MB may be formed to cover the first semiconductor chip SC1 and the plurality of conductive posts 240. Here, a CMP process may be performed such that the first semiconductor chip SC1, the plurality of conductive posts 240, and the molding member MB have top surfaces at the same vertical level.

Thereafter, an external connection terminal 500 may be adhered to a bottom surface of the first wiring structure 100. However, unlike described above, the process of adhering the external connection terminal 500 may be performed as a subsequent process.

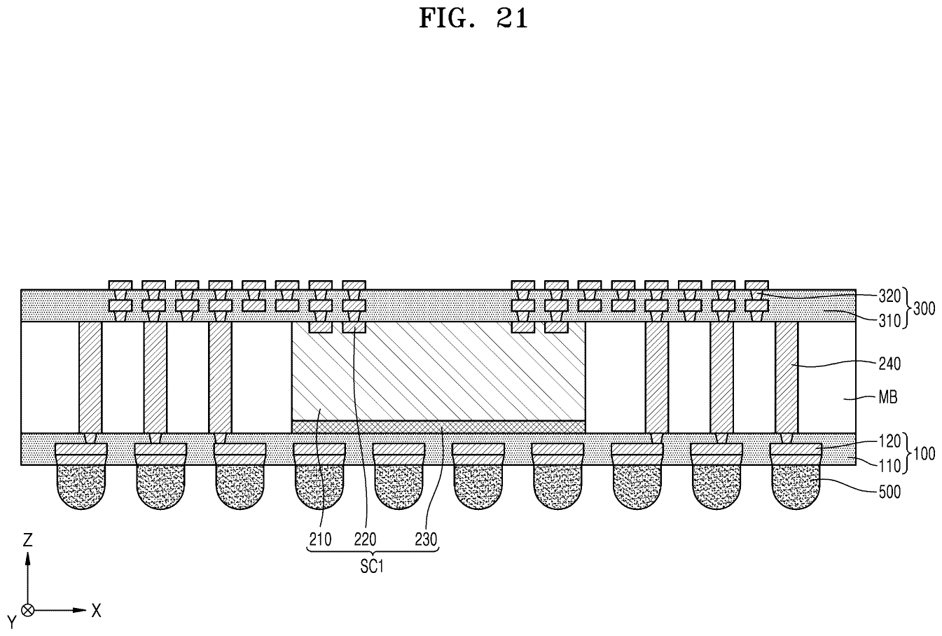

Referring to FIG. 21, a second wiring structure 300 including a second insulating layer 310 and a plurality of second conductive patterns 320 may be formed on the plurality of conductive posts 240 and the molding member MB (also called molding encapsulant in the present disclosure).

In the second wiring structure 300, the second insulating layer 310 may be formed to surround the plurality of second conductive patterns 320. In some implementations, the second wiring structure 300 may include a plurality of second insulating layers 310 that are stacked.

The plurality of second conductive patterns 320 may be connected to the plurality of conductive posts 240 located under the second wiring structure 300 and to the plurality of upper connection pads 220 of the first semiconductor chip SC1.

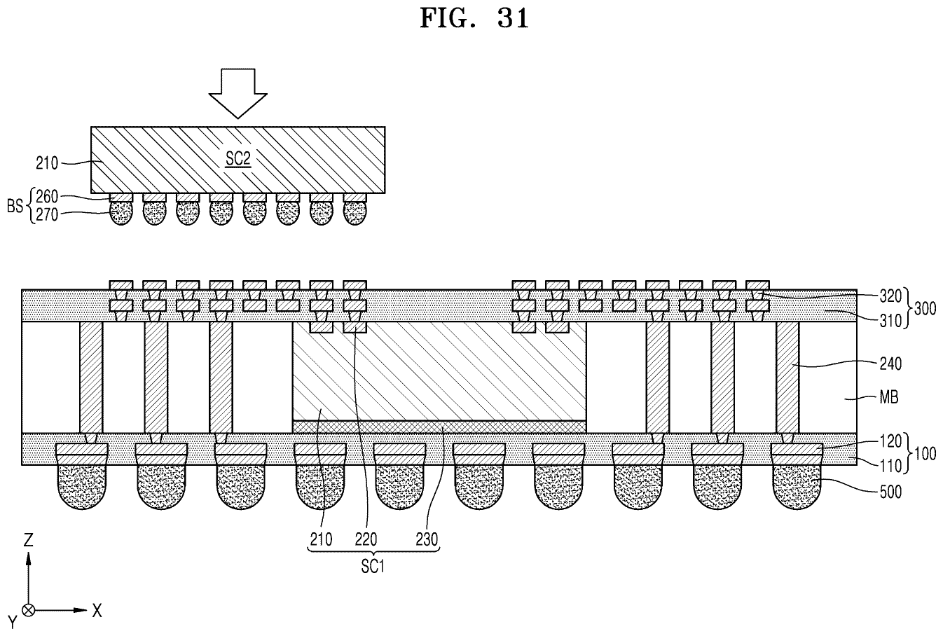

Referring to FIG. 22, a semiconductor substrate 210 of a second semiconductor chip SC2 on which an electrode pad 222 (referring to FIG. 23) that may externally expand an integrated circuit function of an individual unit device is formed may be provided. The second semiconductor chip SC2 can be the second semiconductor chip SC2 of FIG. 31.

The semiconductor substrate 210 may include, for example, a semiconductor material, such as silicon (Si) or germanium (Ge). Alternatively, the semiconductor substrate 210 may include a compound semiconductor material, such as silicon carbide (SiC), gallium arsenide (GaAs), indium arsenide (InAs), and indium phosphide (InP).

Here, positions of the plurality of bump pads 260 and the plurality of solder bumps 270 to be described below are illustrated with dashed lines on the semiconductor substrate 210.

Referring to FIG. 23, a protective layer 250 having an open region 250H may be formed on the semiconductor substrate 210.

A preliminary protective layer may be formed on the semiconductor substrate 210 and then patterned by using a photolithography process and an etching process, and thus, the protective layer 250 including the opening region 250H exposing a central portion of the electrode pad 222 may be formed.

The protective layer 250 may be on the semiconductor substrate 210 except for a region in which the electrode pad 222 is formed, and may serve as an insulating layer. Also, the protective layer 250 may protect a top surface of the semiconductor substrate 210 from external impurities and physical shocks. In some implementations, the protective layer 250 may be formed using a plurality of material layers.

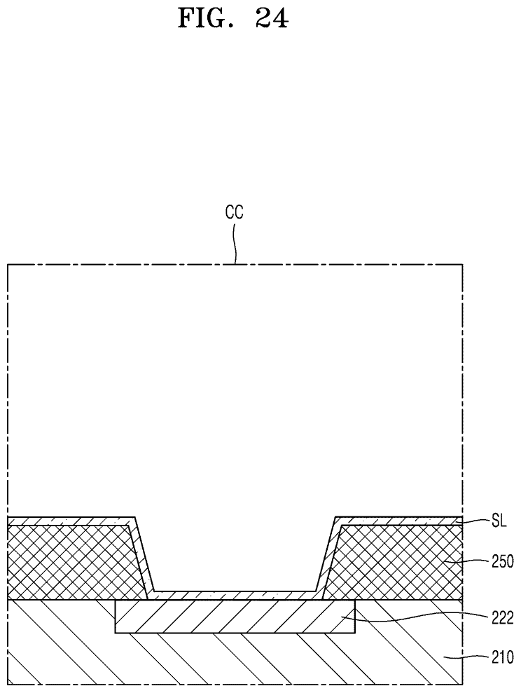

Referring to FIG. 24, a seed layer SL may be formed on the semiconductor substrate 210 and the protective layer 250.

The seed layer SL may be formed on the exposed top surface of the semiconductor substrate 210 and the entire surface of the protective layer 250 and be formed to a thickness of about 100 angstroms (Å) to about 0.5 μm. The seed layer SL may include, for example, a metal, such as copper (Cu), nickel (Ni), titanium (Ti), tungsten (W), tin (Sn), and silver (Ag) or an alloy thereof and include a single layer or a multilayered structure.

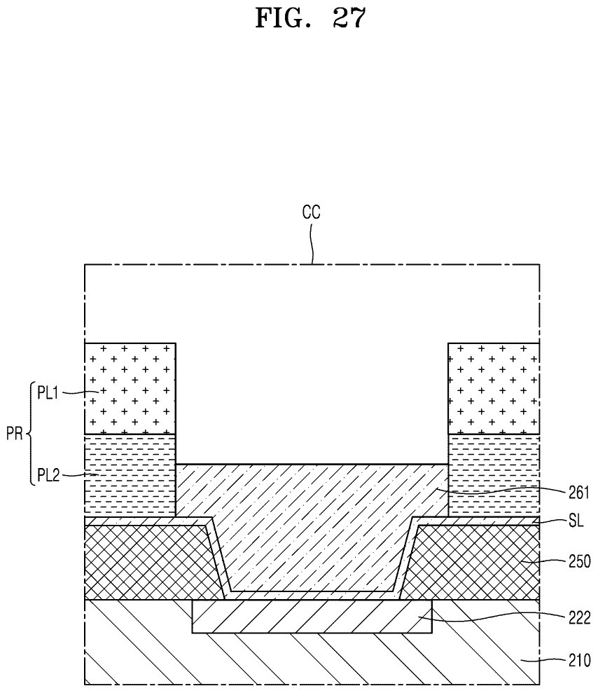

The seed layer SL may serve as a seed for forming a first bump pad (refer to 261 in FIG. 27). That is, when the first bump pad (refer to 261 in FIG. 27) is formed using a plating process, the seed layer SL may provide a path through which current may flow, and thus, the first bump pad (refer to 261 in FIG. 27) may be formed on the seed layer SL.

Referring to FIG. 25, a dry resist film DF may be provided to be used as a photomask.

Characteristics of each component included in the dry resist film DF may substantially be the same as those described above with reference to FIG. 12. Thus, a detailed description thereof is omitted.

Next, the release film (refer to RF in FIG. 12) may be removed from the dry resist film DF, and the second photoresist layer PL2 may be adhered to the resultant structure such that a bottom surface of the second photoresist layer PL2 covers the seed layer SL.

The second photoresist layer PL2 may entirely cover a top surface of the seed layer SL. Also, the second photoresist layer PL2 may be conformally modified along a shape of the seed layer SL.

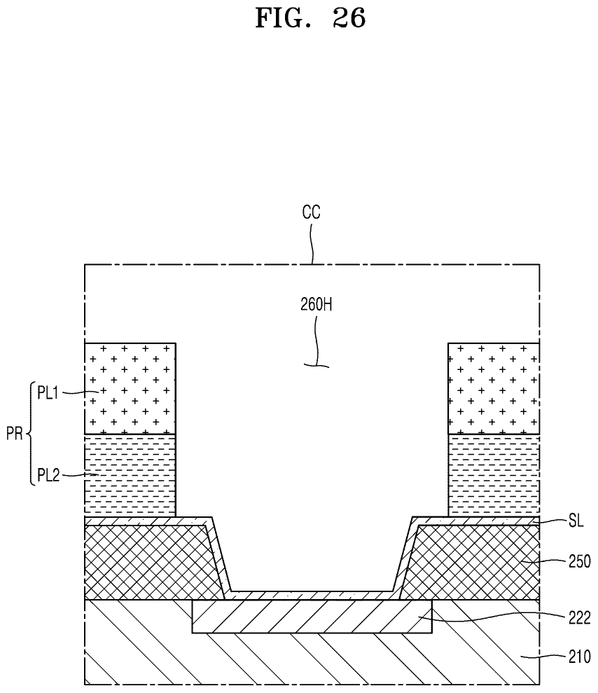

Referring to FIG. 26, the base film (refer to BF in FIG. 25) may be removed from the dry resist film (refer to DF in FIG. 25), and a multilayered photoresist film PR may be exposed and developed to form an opening 260H.

By performing the exposure process and the development process, the opening 260H having a high aspect ratio may be formed on the seed layer SL corresponding to the opening region (refer to 250H in FIG. 23) of the protective layer 250. To improve a phenomenon where a width of the opening 260H having a high aspect ratio becomes excessively greater or less than an intended width, an exposure process and a development process may be performed by using the multilayered photoresist film PR.

By adjusting contents of polymers and/or additives included in the first and second photoresist layers PL1 and PL2 that constitute the multilayered photoresist film PR, chemical resistances and resolutions of the multilayered photoresist film PR may be adjusted.

In the above-described manner, in the multilayered photoresist film PR, the first photoresist layer PL1 located at an upper side may be free from problems, such as cracks, because the first photoresist layer PL1 has high chemical resistance and shrinkage resistance, while the second photoresist layer PL2 located at a lower side may have a high resolution, and thus, a high-resolution environment may be implemented in which a predetermined amount of light or more may be transmitted to a lower portion of the multilayered photoresist film PR.

Referring to FIG. 27, a portion of the opening 260H may be filled by a conductive material, and thus, a first bump pad 261 may be formed on the seed layer SL.

The first bump pad 261 may be formed using a plating process. In some implementations, the first bump pad 261 may include copper (Cu) or a copper (Cu) alloy, without being limited thereto.

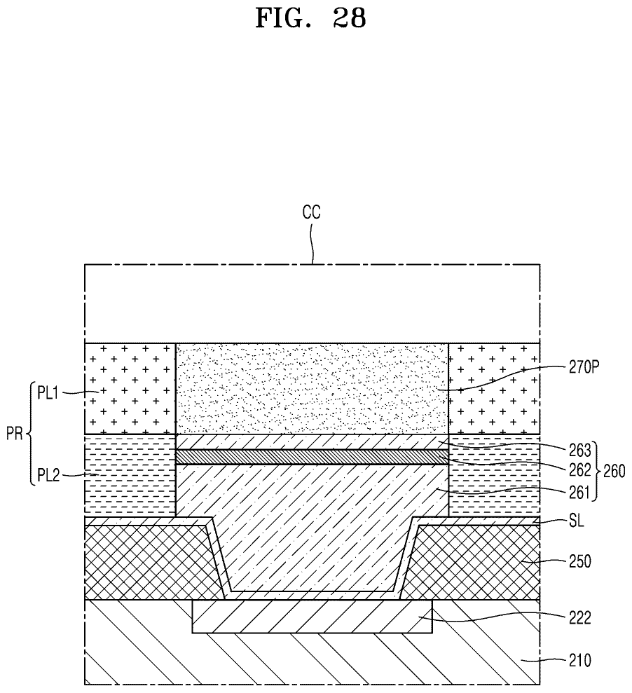

Referring to FIG. 28, second and third bump pads 262 and 263 may be sequentially formed on the first bump pad 261.

Accordingly, the first to third bump pads 261, 262, and 263 may constitute a bump pad 260. The bump pad 260 may have, for example, a multilayered structure of a plurality of metals selected from copper (Cu), nickel (Ni), and gold (Au).

Next, a preliminary solder layer 270P may be formed on the bump pad 260. A top surface of the preliminary solder layer 270P may substantially be the same as a top surface of the multilayered photoresist film PR. The preliminary solder layer 270P may be formed using a plating process. The preliminary solder layer 270P may include, for example, an alloy of tin (Sn) and silver (Ag), and small amounts of copper (Cu), palladium (Pd), bismuth (Bi), and/or antimony (Sb) may be added to the preliminary solder layer 270P. In some implementations, the preliminary solder layer 270P and the bump pad 260 have different slopes, similar to the conductive posts shown in FIG. 3.

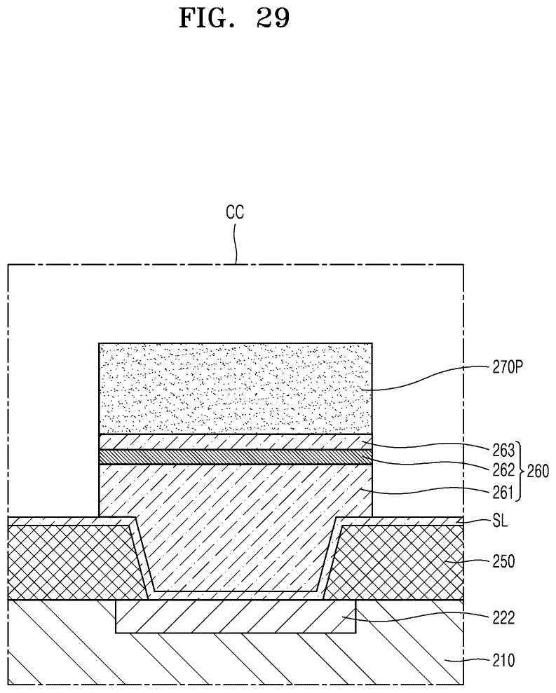

Referring to FIG. 29, the multilayered photoresist film (refer to PR in FIG. 28) may be completely removed.

The multilayered photoresist film (refer to PR in FIG. 28) may be removed using a strip process and/or an ashing process. By removing the multilayered photoresist film (refer to PR in FIG. 28), the seed layer SL, the bump pad 260, and the preliminary solder layer 270P may be exposed to the outside.

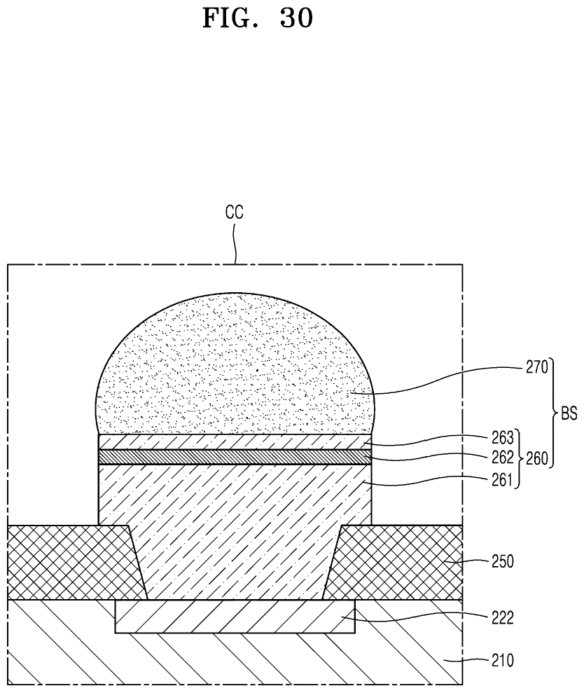

Referring to FIG. 30, the seed layer (refer to SL in FIG. 29) may be removed around the bump pad 260 and the preliminary solder layer (refer to 270P in FIG. 29).

The seed layer (refer to SL in FIG. 29) exposed to the outside may be etched by using the bump pad 260 and the preliminary solder layer (refer to 270P in FIG. 29) as an etch mask. The etching process may be a wet etching process, which is an isotropic etching process. For example, when a constituent material of the seed layer (refer to SL in FIG. 29) includes copper (Cu), the seed layer SL may be removed using an ammonia etching process.

Next, a reflow process may be performed on the preliminary solder layer (refer to 270P in FIG. 29). The reflow process may be performed at a temperature of about 220° C. to about 260° C. The preliminary solder layer (refer to 270P in FIG. 29) may melt due to the reflow process, and thus, the solder bump 270 may be formed.

The preliminary solder layer (refer to 270P in FIG. 29) may not collapse after melting, and may form the solder bump 270 on the bump pad 260 due to surface tension, and an intermetallic compound may be formed at an interface between the bump pad 260 and the solder bump 270. Thus, a bump structure BS including the bump pad 260 and the solder bump 270 may be formed. Simultaneously, an interface between the first bump pad 261 and the seed layer (refer to SL in FIG. 29) may disappear.

Referring to FIG. 31, a second semiconductor chip SC2 may be formed by performing the process.

The second semiconductor chip SC2 including a plurality of bump structures BS may be mounted on the second wiring structure 300. A bottom surface of the second semiconductor chip SC2 may be arranged to face a top surface of the second wiring structure 300 such that the plurality of bump structures BS come into contact with the plurality of second conductive patterns 320. In some implementations, a process of adhering the plurality of bump structures BS to the plurality of second conductive patterns 320 may be performed at a sufficiently high temperature to melt a portion of the solder bump 270.

Referring back to FIG. 4, a third semiconductor chip SC3 may be mounted on the second wiring structure 300 in parallel with the second semiconductor chip SC2.

The process of manufacturing the third semiconductor chip SC3 may substantially be the same as the above-described process of manufacturing the second semiconductor chip SC2.

By using the method of manufacturing a semiconductor package as described above, the semiconductor package 20 according to the present disclosure may be manufactured.

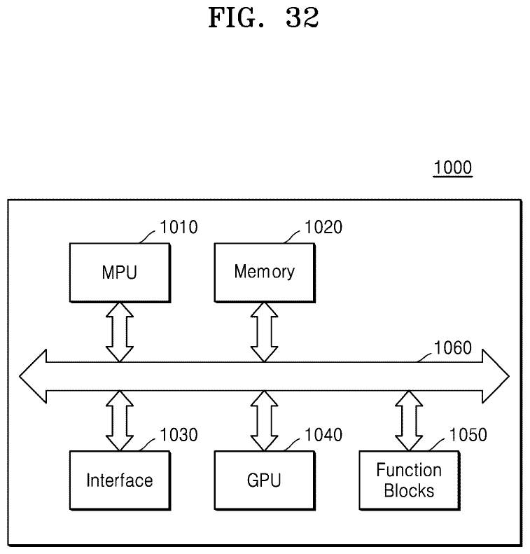

FIG. 32 is a view showing the configuration of a semiconductor package 1000 according to implementations.

Referring to FIG. 32, the semiconductor package 1000 may include a microprocessing unit (MPU) 1010, a memory 1020, an interface 1030, a GPU 1040, function blocks 1050, and a bus 1060 configured to connect the MPU 1010, the memory 1020, the interface 1020, the GPU 1040, and the function blocks 1050 to each other.

The semiconductor package 1000 may include at least one of the MPU 1010 and the GPU 1040.

The MPU 1010 may include a core and a cache. For example, the MPU 1010 may include a multi-core. Respective cores of the multi-core may have the same performance or different performances. Also, the respective cores of the multi-core may be activated simultaneously or at different points in time.

The memory 1020 may store results processed by the function blocks 1050 via the control of the MPU 1010. The interface 1030 may exchange information or signals with external devices. The GPU 1040 may perform graphics functions. For example, the GPU 1040 may perform a video codec or process 3D graphics. The function blocks 1050 may perform various functions. For example, when the semiconductor package 1000 is an AP used for a mobile device, some of the function blocks 1050 may perform communication functions.

The semiconductor package 1000 may include the semiconductor packages 10 and 20 described above and/or semiconductor packages manufactured by using the methods S10 and S20 of manufacturing semiconductor packages, which are described above.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method of manufacturing a semiconductor package, the method comprising:
stacking a plurality of semiconductor chips including a first semiconductor chip and a second semiconductor chip being arranged under the first semiconductor chip, the first semiconductor ship being offset from the second semiconductor ship in a lateral direction to thereby expose a plurality of upper connection pads formed on an outer region of a top surface of the second semiconductor chip;
forming a multilayered photoresist film to cover the plurality of semiconductor chips;
forming a plurality of openings above the outer region of the top surface of the second semiconductor chip by exposing and developing the multilayered photoresist film;
forming a plurality of conductive posts by filling the plurality of openings with a conductive material, the plurality of conductive posts being respectively connected to the plurality of upper connection pads on the outer region of the top surface of the second semiconductor chip;
removing the multilayered photoresist film;
forming a molding encapsulant to surround the plurality of semiconductor chips and the plurality of conductive posts; and
forming a wiring structure on the molding encapsulant, the wiring structure being electrically connected to the plurality of conductive posts,
wherein the multilayered photoresist film comprises at least two layers having different chemical resistances and resolutions.

2. The method of claim 1, wherein forming the multilayered photoresist film to cover the plurality of semiconductor chips comprises:
adhering, onto a base film, a first photoresist layer having a first chemical resistance and a first resolution;
adhering, onto the first photoresist layer, a second photoresist layer having a second chemical resistance and a second resolution;
adhering the second photoresist layer onto the plurality of semiconductor chips such that the plurality of semiconductor chips are covered by a surface of the second photoresist layer; and
removing the base film from the first photoresist layer,
wherein the first chemical resistance is higher than the second chemical resistance, and the first resolution is lower than the second resolution.

3. The method of claim 2, wherein forming the plurality of conductive posts comprises forming the plurality of conductive posts each including:
a first portion having a sidewall in contact with the first photoresist layer; and
a second portion having a sidewall in contact with the second photoresist layer,
wherein a slope of the sidewall of the first portion is different from a slope of the sidewall of the second portion.

4. The method of claim 3, wherein forming the plurality of conductive posts comprises forming the plurality of conductive posts by a single plating process.

5. The method of claim 2, wherein the multilayered photoresist film comprises negative photoresist.

6. The method of claim 5, wherein a molecular weight of a main polymer of the first photoresist layer is greater than a molecular weight of a main polymer of the second photoresist layer.

7. The method of claim 6, wherein the first photoresist layer is hydrophobic, and the second photoresist layer is hydrophilic.

8. The method of claim 2, wherein the multilayered photoresist film comprises positive photoresist.

9. The method of claim 8, wherein a molecular weight of polyhydroxystyrene (PHS) of the first photoresist layer is greater than a molecular weight of PHS of the second photoresist layer.

10. The method of claim 9, wherein an addition amount of a photo active compound (PAC) of the first photoresist layer is smaller than an addition amount of a PAC of the second photoresist layer.

11. A method of manufacturing a semiconductor package, the method comprising:
providing a semiconductor substrate comprising a plurality of electrode pads;
forming, on the semiconductor substrate, a protective layer exposing the plurality of electrode pads;
forming a seed layer to cover the protective layer and the plurality of electrode pads;
forming a multilayered photoresist film to cover the seed layer;
forming a plurality of openings exposing the seed layer on the plurality of electrode pads by exposing and developing the multilayered photoresist film;
forming a plurality of bump structures by filling the plurality of openings with a conductive material, the plurality of bump structures being configured to be connected to the plurality of electrode pads in the semiconductor substrate;
removing the multilayered photoresist film; and
removing an exposed portion of the seed layer that is around the plurality of bump structures,
wherein the multilayered photoresist film comprises at least two layers having different chemical resistances and resolutions.

12. The method of claim 11, wherein forming the multilayered photoresist film to cover the seed layer comprises:
adhering, onto a base film, a first photoresist layer having a first chemical resistance and a first resolution;
adhering, onto the first photoresist layer, a second photoresist layer having a second chemical resistance and a second resolution;
adhering the second photoresist layer onto the seed layer such that the seed layer is covered by a surface of the second photoresist layer; and
removing the base film from the first photoresist layer,
wherein the first chemical resistance is higher than the second chemical resistance, and the first resolution is lower than the second resolution.

13. The method of claim 12, wherein forming the plurality of bump structures comprises forming the plurality of bump structures each including:
a first portion having a sidewall in contact with the first photoresist layer; and
a second portion having a sidewall in contact with the second photoresist layer,
wherein a slope of the sidewall of the first portion is different from a slope of the sidewall of the second portion.

14. The method of claim 12, wherein the multilayered photoresist film comprises negative photoresist.

15. The method of claim 14, wherein a molecular weight of a main polymer of the first photoresist layer is greater than a molecular weight of a main polymer of the second photoresist layer, and
the first photoresist layer is hydrophobic, and the second photoresist layer is hydrophilic.

16. The method of claim 12, wherein the multilayered photoresist film comprises positive photoresist.

17. The method of claim 16, wherein a molecular weight of polyhydroxystyrene (PHS) of the first photoresist layer is greater than a molecular weight of PHS of the second photoresist layer, and
an addition amount of a photo active compound (PAC) of the first photoresist layer is smaller than an addition amount of a PAC of the second photoresist layer.

18. A semiconductor package comprising:
a package substrate;
a plurality of semiconductor chips stacked on the package substrate, the plurality of semiconductor chips including a first semiconductor chip and a second semiconductor chip being arranged under the first semiconductor chip, the first semiconductor chip being offset from the second semiconductor ship in a lateral direction to thereby expose a plurality of upper connection pads formed on an outer region of a top surface of the second semiconductor chip;
a plurality of conductive posts respectively connected to the plurality of upper connection pads on the outer region of the top surface of the second semiconductor chip;
a molding encapsulant surrounding the plurality of semiconductor chips and the plurality of conductive posts; and
a wiring structure on the molding encapsulant, the wiring structure being electrically connected to the plurality of conductive posts,
wherein each of the plurality of conductive posts comprises a lower portion and an upper portion on the upper connection pad, and
a slope of a sidewall of the lower portion is different from a slope of a sidewall of the upper portion.

19. The semiconductor package of claim 18, wherein a length of each of the plurality of conductive posts in a vertical direction is in a range of 100 μm to 1000 μm, and
an aspect ratio of each of the plurality of conductive posts is 8 or higher.

20. The semiconductor package of claim 18, wherein, in each of the plurality of conductive posts, the lower portion is integrally formed with the upper portion.
